(19) United States
(12) Patent Application Publication
(10) Pub. No.: US 2024/0026254 A1
(43) Pub. Date: Jan. 25, 2024

(54) CLEANING LIQUID FOR SEMICONDUCTOR SUBSTRATE

(71) Applicant: FUJIFILM Corporation, Tokyo (JP)

(72) Inventors: Shimpei YAMADA, Haibara-gun (JP); Tetsuya KAMIMURA, Haibara-gun (JP); Naoko OUCHI, Haibara-gun (JP); Naotsugu MURO, Haibara-gun (JP); Nobuaki SUGIMURA, Haibara-gun (JP); Yuta SHIGENOI, Haibara-gun (JP)

(73) Assignee: FUJIFILM Corporation, Tokyo (JP)

(21) Appl. No.: 18/356,507

(22) Filed: Jul. 21, 2023

Related U.S. Application Data
(63) Continuation of application No. PCT/JP2022/002786, filed on Jan. 26, 2022.

(30) Foreign Application Priority Data
Feb. 3, 2021 (JP) 2021-015661
Sep. 17, 2021 (JP) 2021-151772
Dec. 9, 2021 (JP) 2021-200120

(51) Int. Cl. C11D 11/00; C11D 3/30; C11D 3/20

(52) U.S. Cl. CPC C11D 11/0047; C11D 3/30; C11D 3/2096; H01L 21/02065

(57) ABSTRACT

An object of the present invention is to provide a cleaning liquid for a semiconductor substrate, which has excellent cleaning performance and excellent ruthenium oxide dissolving ability in a case of being applied as a cleaning liquid after a CMP treatment of a semiconductor substrate including a metal film. A cleaning liquid for a semiconductor substrate according to the present invention is a cleaning liquid for a semiconductor substrate, which is used for cleaning a semiconductor substrate, where the cleaning liquid contains at least one purine compound selected from the group consisting of purine and a purine derivative and a compound represented by Formula (A).

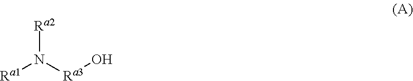

### BACKGROUND OF THE INVENTION

### 1. Field of the Invention

The present invention relates to a cleaning liquid for a semiconductor substrate.

### 2. Description of the Related Art

Semiconductor elements such as a charge-coupled device (CCD) and a memory are manufactured by forming a fine electronic circuit pattern on a substrate by using a photolithographic technique. Specifically, semiconductor elements are manufactured by forming a resist film on a laminate that has a metal film serving as a wiring line material, an etching stop layer, and an interlayer insulating layer on a substrate, and carrying out a photolithography step and a dry etching step (for example, a plasma etching treatment).

In the manufacture of a semiconductor element, a chemical mechanical polishing (CMP) treatment in which a surface of a semiconductor substrate having a metal wiring line film, a barrier metal, an insulating film, or the like is flattened using a polishing slurry including polishing fine particles (for example, silica and alumina) may be carried out. In the CMP treatment, polishing fine particles to be used in the CMP treatment, a polished wiring line metal film, and/or a metal component derived from a barrier metal and the like easily remain on a surface of a semiconductor substrate after polishing.

Since these residues can short-circuit wiring lines and affect the electrical characteristics of a semiconductor, a cleaning step in which these residues are removed from the surface of the semiconductor substrate is generally carried out.

As a cleaning liquid that is used in the cleaning step, for example, JP2016-074906A discloses “a cleaning composition containing at least one solvent, at least one corrosion inhibitor, at least one amine, and at least one quatemary base, where the corrosion inhibitor is one substance selected from the group consisting of ribosyl purine and a methylated or deoxy derivative thereof, adenosine and a decomposition product of an adenosine derivative, a purine-saccharide complex, a methylated or deoxy purine derivative and a reaction product or decomposition product thereof, and a combination thereof”.

### SUMMARY OF THE INVENTION

As a result of studying the cleaning liquid for a semiconductor substrate described in JP2016-074906A, the inventors of the present invention found that there is room for improvement in both the cleaning performance and the ruthenium oxide dissolving ability regarding a cleaning liquid for a semiconductor substrate, which is used for a semiconductor substrate which has been subjected to CMP, where the semiconductor substrate includes a metal film (particularly, a film of the ruthenium metal).

The cleaning performance is a performance that indicates a degree of difficulty that, in a case where a semiconductor substrate including a metal film (particularly, a film of the ruthenium metal) is subjected to a CMP treatment using a polishing liquid and furthermore is subjected to a cleaning step using a cleaning liquid for a semiconductor substrate, the polishing liquid used in the CMP treatment, an organic residue derived from the semiconductor substrate (for example, an insulating film), and the like remain on the semiconductor substrate even after the cleaning step. That is, the excellent cleaning performance means that an organic residue and the like are difficult to remain on a semiconductor substrate.

In addition, in a case where a semiconductor substrate including a metal film (particularly, a film of the ruthenium metal) is subjected to the CMP treatment using a polishing liquid, the metal constituting a metal film (particularly, a film of the ruthenium metal) may be oxidized, whereby a metal oxide (particularly, ruthenium oxide) may be generated. The ruthenium oxide dissolving ability is a performance that indicates a degree of difficulty (easiness of dissolution) that the metal oxide (particularly, the oxide of the ruthenium metal) remains on the semiconductor substrate even after the cleaning step. That is, the excellent ruthenium oxide dissolving ability means that ruthenium oxide is easily dissolved on a semiconductor substrate, and thus the ruthenium oxide is difficult to remain on the semiconductor substrate.

An object of the present invention is to provide a cleaning liquid for a semiconductor substrate, which has excellent cleaning performance and excellent ruthenium oxide dissolving ability in a case of being applied as a cleaning liquid after a CMP treatment of a semiconductor substrate including a metal film (particularly, a film of the ruthenium metal).

The inventors of the present invention have found that the objects can be accomplished by the following configurations.

[1]

A cleaning liquid for a semiconductor substrate, which is used for cleaning a semiconductor substrate, the cleaning liquid comprising:
at least one purine compound selected from the group consisting of purine and a purine derivative; and
a compound represented by Formula (A) described later.

[2]

The cleaning liquid for a semiconductor substrate according to [1], in which the purine compound includes at least one selected from the group consisting of compounds represented by Formulae (B5) and (B6) described later.

[3]

The cleaning liquid for a semiconductor substrate according to [1], in which the purine compound includes at least one selected from the group consisting of xanthine, adenine, guanine, hypoxanthine, uric acid, purine, caffeine, isoguanine, theobromine, theophylline, and paraxanthine.

[4]

The cleaning liquid for a semiconductor substrate according to any one of [1] to [3], in which the purine compound includes at least one selected from the group consisting of xanthine and hypoxanthine.

[5]

The cleaning liquid for a semiconductor substrate according to any one of [1] to [4], in which the compound represented by Formula (A) includes a compound represented by Formula (A1) described later.

[6]

The cleaning liquid for a semiconductor substrate according to any one of [1] to [5], in which the compound represented by Formula (A) includes N-methyldiethanolamine.

[7]

The cleaning liquid for a semiconductor substrate according to any one of [1] to [6], in which a content of the purine compound is 0.5% to 30.0% by mass with respect to a total mass of components of the cleaning liquid for a semiconductor substrate excluding a solvent.

[8]

The cleaning liquid for a semiconductor substrate according to any one of [1] to [7], in which a content of the compound represented by Formula (A) is 3.0% to 40.0% by mass with respect to a total mass of components of the cleaning liquid for a semiconductor substrate excluding a solvent.

[9]

The cleaning liquid for a semiconductor substrate according to any one of [1] to [8], in which a mass ratio of a content of the purine compound to a content of the compound represented by Formula (A) is 0.02 to 20.0.

[10]

The cleaning liquid for a semiconductor substrate according to any one of [1] to [9], in which a pH is 9.5 to 13.0.

[11]

The cleaning liquid for a semiconductor substrate according to any one of [1] to [10], further comprising an organic acid.

[12]

The cleaning liquid for a semiconductor substrate according to [11], in which the organic acid includes a compound represented by Formula (D) described later.

[13]

The cleaning liquid for a semiconductor substrate according to any one of [1] to [12], further comprising a quaternary ammonium compound.

[14]

The cleaning liquid for a semiconductor substrate according to [13], in which the quatemary ammonium compound includes a compound represented by Formula (C) described later.

[15]

The cleaning liquid for a semiconductor substrate according to [13] or [14], in which the quatemary ammonium compound includes tris(2-hydroxyethyl)methylammonium hydroxide.

[16]

The cleaning liquid for a semiconductor substrate according to any one of [1] to [15], further comprising an aliphatic tertiary amine compound which is a compound different from the compound represented by Formula (A).

[17]

The cleaning liquid for a semiconductor substrate according to [16], in which the aliphatic tertiary amine compound has two or more nitrogen atoms.

According to the present invention, there is provided a cleaning liquid for a semiconductor substrate, which has excellent cleaning performance and excellent ruthenium oxide dissolving ability in a case of being applied as a cleaning liquid after CMP of a semiconductor substrate including a metal film (particularly, a film of the ruthenium metal).

### DESCRIPTION OF THE PREFERRED EMBODIMENTS

Hereinafter, an example of a form for carrying out the present invention will be described.

In the present specification, a numerical value range expressed using “to” means a range that includes the preceding and succeeding numerical values of “to” as the lower limit and the upper limit, respectively.

In the present specification, in a case where two or more kinds of a certain component are present, the “content” of the component means the total content of the two or more kinds of the component.

In the present specification, “ppm” means “parts-per-million (10⁻⁶)”, and “ppb” means “parts-per-billion (10⁻⁹)”.

The compounds described in the present specification may include, unless otherwise specified, isomers (compounds having the same number of atoms but having different structures), optical isomers, and isotopes thereof. In addition, only one kind or a plurality of kinds of the isomers and the isotopes may be included.

The bonding direction of the divalent group (for example, —COO—) denoted in the present specification, is not limited unless otherwise specified. For example, in a case where Y is —COO— in a compound represented by a formula of “X—Y—Z”, the above-described compound may be “X—O—CO—Z” or may be “X—CO—O—Z”.

In the present specification, “psi” means pound-force per square inch, where 1 psi=6,894.76 Pa.

In the present specification, the “weight-average molecular weight” means a weight-average molecular weight in terms of polyethylene glycol measured by gel permeation chromatography (GPC).

In the present specification, “the total mass of the components in the cleaning liquid excluding the solvent” means the total content of all components contained in the cleaning liquid other than the solvent such as water or an organic solvent.

[Cleaning Liquid for Semiconductor Substrate (Cleaning Liquid)]

The cleaning liquid for a semiconductor substrate (hereinafter, also simply referred to as a “cleaning liquid”) according to the embodiment of the present invention is a cleaning liquid for a semiconductor substrate, which is used for cleaning a semiconductor substrate, where the cleaning liquid contains at least one purine compound (hereinafter, also simply referred to as a “purine compound”) selected from the group consisting of purine and a purine derivative and contains a compound (hereinafter, also referred to as a “compound A”) represented by Formula (A).

Although the mechanism by which the object of the present invention is achieved by the above-described configurations is not always clear, it is conceived that the respective components act cooperatively, and thus the cleaning performance is excellent, and the ruthenium oxide dissolving ability is also excellent since the purine compound and the compound A are present together.

For example, it is presumed that the purine compound and the compound A interact with a residue on the surface of the semiconductor substrate after the CMP treatment and with the surface of the substrate, thereby contributing to the improvement of the cleaning performance and the improvement of the ruthenium oxide dissolving ability.

Hereinafter, the fact that at least one of the cleaning performance or the ruthenium oxide dissolving ability is more excellent is also referred to as that the effect of the present invention is more excellent.

Hereinafter, each component included in the cleaning liquid will be described.

[Compound A]

The cleaning liquid contains the compound A (the compound represented by Formula (A).

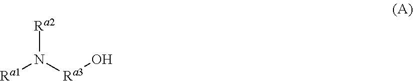

In Formula (A), R^{a1} represents an alkyl group which may have a hydroxyl group. R^{a2} represents a hydrogen atom, an alkyl group which may have a substituent, or an aryl group which may have a substituent. R^{a3} represents an alkylene group which may have an oxygen atom.

R^{a1} represents an alkyl group which may have a hydroxyl group.

The alkyl group may be linear, branched, or cyclic.

The alkyl group preferably has 1 to 10 carbon atoms, more preferably has 1 to 5 carbon atoms, still more preferably has 1 to 3 carbon atoms, and particularly preferably has two carbon atoms.

The hydroxyl group contained in the alkyl group preferably has 1 to 5 carbon atoms, more preferably 1 to 3 carbon atoms, still more preferably 1 or 2 carbon atoms, and particularly preferably one carbon atom.

R^{a2} represents a hydrogen atom, an alkyl group which may have a substituent, or an aryl group which may have a substituent.

Examples of the substituent contained in the alkyl group include a halogen atom such as a fluorine atom, a chlorine atom, or a bromine atom; an alkoxy group; a hydroxyl group; a carboxy group; an alkoxycarbonyl group such as a methoxycarbonyl group or an ethoxycarbonyl group; an acyl group such as an acetyl group, a propionyl group, or benzoyl group; a cyano group; a nitro group; and an amino group, where a hydroxyl group, a carboxy group, or an amino group is preferable, and a hydroxyl group is more preferable.

Among them, R^{a2} is preferably a hydrogen atom, an alkyl group which may have a hydroxyl group, or an aryl group which may have a substituent, more preferably a hydrogen atom, an unsubstituted alkyl group having 1 to 3 carbon atoms, or an aryl group which may have a substituent, still more preferably a hydrogen atom, a methyl group, an ethyl group, a tert-butyl group, or a phenyl group, and particularly preferably a methyl group.

The alkyl group may be linear, branched, or cyclic.

The alkyl group preferably has 1 to 20 carbon atoms, more preferably has 1 to 10 carbon atoms, still more preferably has 1 to 5 carbon atoms, and particularly preferably has 1 to 3 carbon atoms.

In a case where the alkyl group has a hydroxyl group, the number of hydroxyl groups contained in the alkyl group is preferably 1 to 5, more preferably 1 to 3, and still more preferably 1.

The aryl group may be any one of a monocyclic ring or a polycyclic ring.

The aryl group preferably has 6 to 20 carbon atoms, more preferably has 6 to 10 carbon atoms, and still more preferably has 6 to 8 carbon atoms.

Examples of the substituent contained in the aryl group include a halogen atom such as a chlorine atom, an alkyl group having 1 to 10 carbon atoms, an alkoxy group having 1 to 10 carbon atoms, a cycloalkoxy group having 3 to 10 carbon atoms, a nitro group, a thiol group, a hydroxyl group, a carboxy group, an amino group, and a dioxirane-yl group, where a halogen atom, an alkyl group having 1 to 10 carbon atoms, a hydroxyl group, a carboxy group, or an amino group is preferable, an alkyl group having 1 to 10 carbon atoms is more preferable, and an alkyl group having 1 to 3 carbon atoms is still more preferable.

The aryl group preferably has 1 to 5 substituents, more preferably has 1 to 3 substituents, and still more preferably has one substituent.

Examples of the aryl group include a benzyl group, a phenyl group, a naphthyl group, an anthryl group, a phenanthryl group, an indenyl group, an acenaphthenyl group, a fluorenyl group, and a pyrenyl group, where a benzyl group or a phenyl group is preferable, and a phenyl group is more preferable.

R^{a3} represents an alkylene group which may have an oxygen atom.

The alkylene group may be linear or branched.

The alkylene group preferably has 1 to 10 carbon atoms, more preferably has 1 or 5 carbon atoms, and still more preferably has 1 to 3 carbon atoms.

The alkylene group preferably has 1 to 5 oxygen atoms, more preferably 1 or 3 oxygen atoms, and still more preferably 1 or 2 oxygen atoms.

Examples of the alkylene group include an alkylene group, an oxyalkylene group, and an alkylene group having a hydroxyl group, where an alkylene group having 1 to 10 carbon atoms or an oxyalkylene group is preferable, an alkylene group having 1 to 10 carbon atoms is more preferable, and an alkylene group having 1 to 3 carbon atoms is still more preferable.

The compound A is preferably a compound represented by Formula (A1).

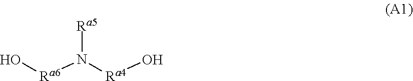

In Formula (A1), R^{a4} represents an alkylene group which may have an oxygen atom. R^{a6} represents an alkylene group. R^{a5} represents an alkyl group having 1 to 5 carbon atoms, which may have a substituent, a phenyl group, or a hydrogen atom.

R^{a4} has the same meaning as R^{a3} in Formula (A), and the same also applies to the suitable aspect thereof.

The alkylene group represented by R^{a6} may be linear, branched, or cyclic.

The alkylene group preferably has 1 to 10 carbon atoms, more preferably has 1 to 5 carbon atoms, still more preferably has 1 to 3 carbon atoms, and particularly preferably has 2 carbon atoms.

R^{a5} is preferably an alkyl group having 1 to 3 carbon atoms, a tert-butyl group, or a phenyl group, and more preferably a methyl group.

The alkyl group may be linear, branched, or cyclic.

Examples of the substituent include a substituent contained in R^{a2} in Formula (A).

Examples of the compound A include N-methylethanolamine (N-MEA), N-methyldiethanolamine (MDEA), 2-(dimethylamino)ethanol (DMAE), 2-(ethylamino)ethanol, 2-[(hydroxymethyl)amino]ethanol, 2-(propylamino)ethanol, N,N-dimethylaminoethoxyethanol, diethanolamine, 2-diethylaminoethanol, N-butylethanolamine, N-ethyldiethanolamine (EDEA), 2-[2-(dimethylamino)ethoxy]ethanol, N-cyclohexylethanolamine, triethanolamine, N-butyldiethanolamine (BDEA), 2-[2-(diethylamino)ethoxy]ethanol, 2-(dimethylamino)-2-methyl-1-propanol (DMAMP), (2-methyl-2-(methylamino)propane-1-ol (MAMP), N-tert-butyldiethanolamine (t-BDEA), 1-[bis(2-hydroxyethyl)amino]-2-propanol (Bis-HEAP), 2-(N-ethylanilino)ethanol, 2-(dibutylamino)ethanol, N-phenyldiethanolamine (Ph-DEA), N-benzyldiethanolamine, p-tolyldiethanolamine, m-tolyldiethanolamine, N,N-bis(2-hydroxyethyl)-3-chloroaniline, and stearyldiethanolamine.

Among them, the compound A preferably includes at least one selected from the group consisting of DMAMP, MAMP, MDEA, t-BDEA, Bis-HEAP, Ph-DEA, EDEA, BDEA, N-MEA, and DMAE, and from the viewpoint of more excellent ruthenium oxide dissolving ability, it more preferably includes at least one selected from the group consisting of MDEA, t-BDEA, Ph-DEA, EDEA, and N-MEA, and still more preferably includes MDEA.

One kind of the compound A may be used alone, or two or more kinds thereof may be used in combination.

The content of the compound A is preferably 0.05% to 20.0% by mass, more preferably 0.2% to 10.0% by mass, and still more preferably 0.3% to 4.0% by mass, with respect to the total mass of the cleaning liquid.

In addition, the content of the compound A is preferably 1.0% to 80.0% by mass, more preferably 2.0% to 60.0% by mass, and still more preferably 3.0% to 40.0% by mass with respect to the total mass of the components in the cleaning liquid excluding the solvent.

In a case where the cleaning liquid does not contain a quaternary ammonium compound described later, it is preferable that the cleaning liquid contains the compound A as a main component from the viewpoint that the effect of the present invention is excellent. In the above case, the compound A can also exhibit the effect of the present invention due to the quatemary ammonium compound. That is, the compound A contained as the main component also has various functions of the quatemary ammonium compound, and thus the same effect as in the case where the quaternary ammonium compound is contained can be obtained.

The “main component” means a component contained by an amount of 50% by mass or more with respect to the total mass of the components in the cleaning liquid excluding the solvent, and it is preferably 60% by mass or more. The upper limit thereof is less than 100% by mass in a large number of cases.

The compound A contained as the main component is preferably 2-(dimethylamino)-2-methyl-1-propanol.

[Purine Compound]

The cleaning liquid contains at least one purine compound selected from the group consisting of purine and a purine derivative.

The purine compound preferably includes at least one selected from the group consisting of compounds represented by Formulae (B1) to (B4), more preferably includes at least one selected from the group consisting of a compound represented by Formula (B1) and compounds represented by Formulae (B4) to (B7), and still more preferably includes at least one selected from the group consisting of compounds represented by Formulae (B5) and (B6).

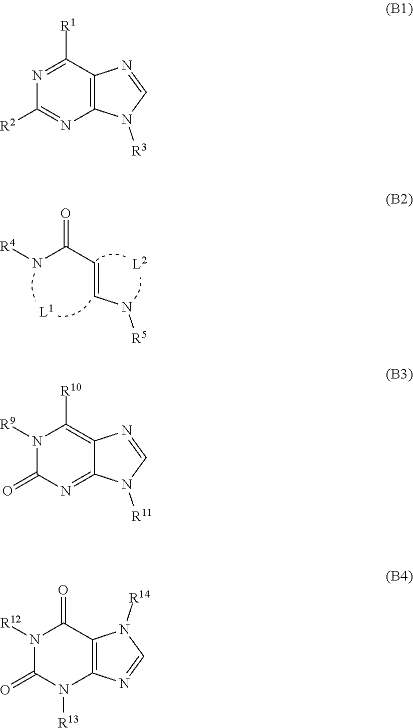

In Formula (B1), R¹ to R³ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

The alkyl group may be linear, branched, or cyclic.

The alkyl group preferably has 1 to 10 carbon atoms, more preferably has 1 to 5 carbon atoms, and still more preferably has 1 to 3 carbon atoms.

Examples of the sugar group include a group obtained by removing one hydrogen atom from saccharides selected from the group consisting of monosaccharides, disaccharides, and polysaccharides, where a group obtained by removing one hydrogen atom from monosaccharides is preferable.

Examples of the monosaccharides include a pentose such as ribose, deoxyribose, arabinose, or xylose, a triose, a tetrose, a hexose, and a heptose, where a pentose is preferable, ribose, deoxyribose, arabinose, or xylose is more preferable, and ribose or deoxyribose is still more preferable.

Examples of the disaccharides include sucrose, lactose, maltose, trehalose, turanose, and cellobiose.

Examples of the polysaccharides include glycogen, starch, and cellulose.

The saccharides may be chain-like or cyclic, and they are preferably cyclic.

Regarding the cyclic saccharides, examples of the ring include a furanose ring and a pyranose ring.

The polyoxyalkylene group-containing group which may have a substituent means a group which has a polyoxyalkylene group which may have a substituent, as a part of the group.

Examples of the polyoxyalkylene group constituting the polyoxyalkylene group-containing group include a polyoxyethylene group, a polyoxypropylene group, and a polyoxybutylene group, where a polyoxyethylene group is preferable.

In addition, the polyoxyalkylene group is also preferably a group represented by Formula (E1) described later.

Examples of the substituent contained in the alkyl group, the amino group, the sugar group, and the polyoxyalkylene group-containing group include a hydrocarbon group such as an alkyl group; a halogen atom such as a fluorine atom, a chlorine atom, or a bromine atom; an alkoxy group; a hydroxyl group; an alkoxycarbonyl group such as a methoxycarbonyl group or an ethoxycarbonyl group; an acyl group such as an acetyl group, a propionyl group, or benzoyl group; a cyano group; and a nitro group.

R¹ is preferably a hydrogen atom or an amino group which may have a substituent, and more preferably a hydrogen atom.

Another suitable aspect of R¹ is preferably a hydrogen atom, an alkyl group which may have a substituent, a thiol group, a hydroxyl group, a halogen atom, a sugar group which may have a substituent, or a polyoxyalkylene group-containing group which may have a substituent.

R² is preferably a hydrogen atom or an alkyl group which may have a substituent, and more preferably a hydrogen atom.

R³ is preferably a hydrogen atom, an alkyl group which may have a substituent, or a sugar group which may have a substituent, more preferably a hydrogen atom or an alkyl group which may have a substituent, and still more preferably a hydrogen atom.

In Formula (B2), L¹ represents —CR⁶═N— or —C(═O)—NR⁷-. L² represents —N═CH— or —NR⁸—C(═O)—. R⁴ to R⁸ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of R⁴ to R⁸ include groups represented by R¹ to R³ in Formula (B1).

R⁴ and R⁵ are preferably a hydrogen atom or an alkyl group which may have a substituent, and more preferably a hydrogen atom.

R⁶ is preferably a hydrogen atom, an alkyl group which may have a substituent, or an amino group which may have a substituent, more preferably a hydrogen atom or an amino group which may have a substituent, and still more preferably a hydrogen atom.

R⁷ is preferably a hydrogen atom or an alkyl group which may have a substituent, and more preferably a hydrogen atom.

L² is preferably —N═CH—.

R⁸ is preferably a hydrogen atom or an alkyl group which may have a substituent, and more preferably a hydrogen atom.

In Formula (B3), R⁹ to R¹¹ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of R⁹ to R¹¹ include groups represented by R¹ to R³ in Formula (B1).

R⁹ is preferably a hydrogen atom or an alkyl group which may have a substituent, and more preferably a hydrogen atom.

R¹⁰ is preferably a hydrogen atom, an alkyl group which may have a substituent, or an amino group which may have a substituent, more preferably a hydrogen atom or an amino group which may have a substituent, and still more preferably an amino group which may have a substituent.

R¹¹ is preferably a hydrogen atom or an alkyl group which may have a substituent, and more preferably a hydrogen atom.

In Formula (B4), R¹² to R¹⁴ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of R¹² to R¹⁴ include groups represented by R¹ to R³ in Formula (B1).

R¹² is preferably a hydrogen atom or an alkyl group which may have a substituent, and more preferably an alkyl group which may have a substituent.

Another suitable aspect of R¹² is preferably an alkyl group which may have a substituent, an amino group which may have a substituent, a thiol group, a hydroxyl group, a halogen atom, a sugar group which may have a substituent, or a polyoxyalkylene group-containing group which may have a substituent.

R¹³ is preferably a hydrogen atom or an alkyl group which may have a substituent, and more preferably an alkyl group which may have a substituent.

R¹⁴ is preferably a hydrogen atom or an alkyl group which may have a substituent.

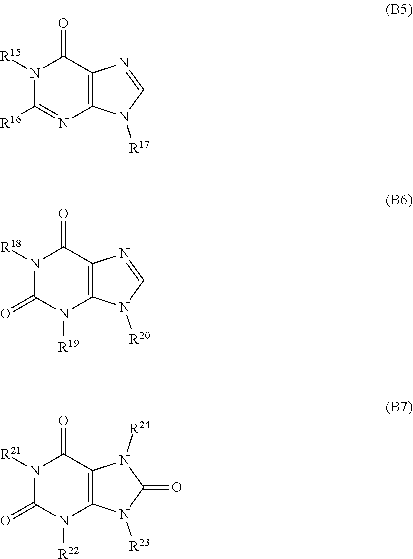

In Formula (B5), R¹⁵ to R¹⁷ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of R¹⁵ to R¹⁷ include groups represented by R¹ to R³ in Formula (B1).

R¹⁵ is preferably a hydrogen atom or an alkyl group which may have a substituent, and more preferably a hydrogen atom.

R¹⁶ is preferably a hydrogen atom, an alkyl group which may have a substituent, or an amino group which may have a substituent, more preferably a hydrogen atom or an amino group which may have a substituent, and still more preferably a hydrogen atom.

Another suitable aspect of R¹⁶ is preferably a hydrogen atom, an alkyl group which may have a substituent, a thiol group, a hydroxyl group, a halogen atom, a sugar group which may have a substituent, or a polyoxyalkylene group-containing group which may have a substituent.

R¹⁷ is preferably a hydrogen atom or an alkyl group which may have a substituent, and more preferably a hydrogen atom.

In Formula (B6), R¹⁸ to R²⁰ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of R¹⁸ to R²⁰ include groups represented by R¹ to R³ in Formula (B1). R¹⁸ to R²⁰ are preferably a hydrogen atom or an alkyl group which may have a substituent, and more preferably a hydrogen atom.

In Formula (B7), R²¹ to R²⁴ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of R²¹ to R²⁴ include groups represented by R¹ to R³ in Formula (B1).

R²¹ to R²⁴ are preferably a hydrogen atom or an alkyl group which may have a substituent, and more preferably a hydrogen atom.

Examples of the purine compound include purine, adenine, guanine, hypoxanthine, xanthine, theobromine, caffeine, uric acid, isoguanine, adenosine, enprofylline, theophylline, xanthosine, 7-methylxanthosine, 7-methylxanthine, theophylline, eritadenine, 3-methyladenine, 3-methylxanthine, 1,7-dimethylxanthine, 1-methylxanthine, 1,3-dipropyl-7-methylxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl)xanthine, 1-butyl-3,7-dimethylxanthine, 3,7-dimethyl-1-propylxanthine, mercaptopurine, 2-aminopurine, 6-aminopurine, 6-benzylaminopurine, nelarabine, vidarabine, 2,6-dichloropurine, aciclovir, N6-benzoyladenosine, trans-zeatin, 6-benzylaminopurine, entecavir, valaciclovir, abacavir, 2′-deoxyguanosine, disodium inosinate, ganciclovir, guanosine 5′-disodium monophosphate, O-cyclohexylmethylguanine, N2-isobutyryl-2′-deoxyguanosine, β-nicotinamide adenine dinucleotide phosphate, 6-chloro-9-(tetrahydropyran-2-yl)purine, clofarabine, kinetin, 7-(2,3-dihydroxypropyl)theophylline, 6-mercaptopurine, proxyphylline, 2,6-diaminopurine, 2′,3′-dideoxyinosine, theophylline-7-acetic acid, 2-chloroadenine, 2-amino-6-chloropurine, 8-bromo-3-methylxanthine, 2-fluoroadenine, penciclovir, 9-(2-hydroxyethyl)adenine, 7-(2-chloroethyl)theophylline, 2-amino-6-iodopurine, 2-thioxanthine, 2-amino-6-methoxypurine, N-acetylguanine, adefovir dipivoxil, 8-chlorotheophylline, 6-methoxypurine, 1-(3-chloropropyl)theobromine, 6-(dimethylamino)purine, and inosine.

Among them, the purine compound preferably includes at least one selected from the group consisting of purine, adenine, guanine, hypoxanthine, xanthine, theobromine, caffeine, uric acid, isoguanine, adenosine, enprofylline, xanthosine, 7-methylxanthosine, 7-methylxanthine, theophylline, eritadenine, paraxanthine, 3-methyladenine, 3-methylxanthine, 1,7-dimethylxanthine, and 1-methylxanthine, more preferably includes at least one selected from the group consisting of xanthine, adenine, guanine, hypoxanthine, uric acid, purine, caffeine, isoguanine, theobromine, theophylline, and paraxanthine, still more preferably includes at least one selected from the group consisting of xanthine, hypoxanthine, uric acid, purine, caffeine, and theophylline, and particularly preferably includes at least one selected from the group consisting of xanthine and hypoxanthine.

One kind of the purine compound may be used alone, or two or more kinds thereof may be used in combination.

The content of the purine compound is preferably 0.01% to 5.0% by mass, more preferably 0.03% to 4.0% by mass, and still more preferably 0.05% to 3.0% by mass, with respect to the total mass of the cleaning liquid.

The content of the purine compound is preferably 0.1% to 50.0% by mass, more preferably 0.3% to 40.0% by mass, and still more preferably 0.5% to 30.0% by mass with respect to the total mass of the components in the cleaning liquid excluding the solvent.

The mass ratio of the content of the purine compound to the content of the compound A (content of purine compound/content of compound A) is preferably 0.002 to 30.0, and it is more preferably 0.02 to 20.0 and still more preferably 0.05 to 10.0 from the viewpoint that the effect of the present invention is more excellent.

[Quaternary Ammonium Compound]

The cleaning liquid may contain a quaternary ammonium compound.

The quaternary ammonium compound is a compound different from the above-described compound that can be contained in the cleaning liquid.

The quatemary ammonium compound is preferably a compound having a quatemary ammonium cation in which a nitrogen atom is substituted with four hydrocarbon groups (preferably alkyl groups). In addition, the quaternary ammonium compound may be a compound having a quatemary ammonium cation in which a nitrogen atom in the pyridine ring is bonded to a substituent (a hydrocarbon group such as an alkyl group or an aryl group), like an alkyl pyridinium.

Examples of the quaternary ammonium compound include a quatemary ammonium hydroxide, a quatemary ammonium fluoride, a quaternary ammonium bromide, a quaternary ammonium iodide, a quaternary ammonium acetate, and a quaternary ammonium carbonate.

The quaternary ammonium compound is preferably a compound represented by Formula (C).

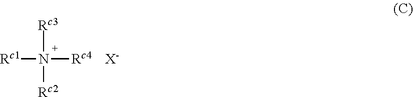

In Formula (C), R^{c1} to R^{c4} each independently represent a hydrocarbon group which may have a substituent. However, a case where all of R^{c1} to R^{c4} represent the same group is excluded. X⁻ represents an anion.

R^{c1} to R^{c4} each independently represent a hydrocarbon group which may have a substituent.

The hydrocarbon group preferably has 1 to 20 carbon atoms, more preferably has 1 to 10 carbon atoms, and still more preferably has 1 to 5 carbon atoms.

Examples of the hydrocarbon group include an alkyl group which may have a substituent, an alkenyl group which may have a substituent, an alkynyl group which may have a substituent, an aryl group which may have a substituent, and a group obtained by combining these, where an alkyl group which may have a substituent is preferable.

Examples of the substituent contained in the hydrocarbon group include a halogen atom such as a fluorine atom, a chlorine atom, or a bromine atom; an alkoxy group; a hydroxyl group; an alkoxycarbonyl group such as a methoxycarbonyl group or an ethoxycarbonyl group; an acyl group such as an acetyl group, a propionyl group, or benzoyl group; and a cyano group; a nitro group, where a hydroxyl group is preferable.

The hydrocarbon group preferably has 1 to 3 substituents and more preferably has one substituent.

The alkyl group, the alkenyl group, and the alkynyl group may be linear, branched, or cyclic.

The alkyl group, the alkenyl group, and the alkynyl group preferably have 1 to 20 carbon atoms, more preferably have 1 to 10 carbon atoms, still more preferably have 1 to 5 carbon atoms, and particularly preferably have 1 to 3 carbon atoms.

Examples of the substituent contained in the alkyl group, the alkenyl group, and the alkynyl include the substituent contained in the hydrocarbon group.

The alkyl group is preferably an unsubstituted alkyl group or a hydroxyalkyl group, more preferably a methyl group, an ethyl group, a propyl group, a butyl group, or a 2-hydroxyethyl group, and still preferably a methyl group, an ethyl group, or a 2-hydroxyethyl group.

The aryl group may be any one of a monocyclic ring or a polycyclic ring.

The aryl group preferably has 6 to 20 carbon atoms, more preferably has 6 to 10 carbon atoms, and still more preferably has 6 to 8 carbon atoms.

Examples of the substituent contained in the aryl group include a halogen atom such as a chlorine atom, an alkyl group having 1 to 10 carbon atoms, an alkoxy group having 1 to 10 carbon atoms, a cycloalkoxy group having 3 to 10 carbon atoms, a nitro group, a thiol group, and a dioxirane-yl group, where a halogen atom or an alkyl group having 1 to 10 carbon atoms is preferable, an alkyl group having 1 to 10 carbon atoms is more preferable, and an alkyl group having 1 to 3 carbon atoms is still more preferable.

The aryl group preferably has 1 to 5 substituents, more preferably has 1 to 3 substituents, and still more preferably has one substituent.

Examples of the aryl group include a benzyl group, a phenyl group, a naphthyl group, an anthryl group, a phenanthryl group, an indenyl group, an acenaphthenyl group, a fluorenyl group, and a pyrenyl group, where a benzyl group or a phenyl group is preferable, and a benzyl group is more preferable.

It is preferable that two or three of R^{c1} to R^{c4} represent the same group, and it is more preferable that three of R^{c1} to R^{c4} represent the same group. For example, it is preferable that R^{c1} to R^{c3} represent a 2-hydroxyethyl group and R^{c4} represents a methyl group.

However, a case where all of R^{c1} to R^{c4} represent the same group is excluded.

For example, a case where all R^{c1} to R^{c4} are methyl groups is excluded. In other words, the compound represented by Formula (C) does not include a tetramethylammonium salt.

X⁻ represents an anion.

Examples of the anion include an acid anion such as a carboxylate ion, a phosphate ion, a sulfate ion, a phosphonate ion, or a nitrate ion, a hydroxide ion, and a halide ion such as a chloride ion, a fluoride ion, or a bromide ion, where a hydroxide ion is preferable.

Examples of the quatemary ammonium compound include tris(2-hydroxyethyl)methylammonium hydroxide (Tris), dimethylbis(2-hydroxyethyl)ammonium hydroxide, tetramethylammonium hydroxide (TMAH), ethyltrimethylammonium hydroxide (ETMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide, where Tris, choline, or ETMAH is preferable.

In addition, from the viewpoint of excellent damage resistance, it is also preferable that the quatemary ammonium compound has an asymmetric structure. The description that the quatemary ammonium compound “has an asymmetric structure” means that none of the four hydrocarbon groups substituted with nitrogen atoms are the same.

Examples of the quaternary ammonium compound having an asymmetric structure include TMEAH, DEDMAH, TEMAH, choline, and bis(2-hydroxyethyl)dimethylammonium hydroxide.

One kind of the quaternary ammonium compound may be used alone, or two or more kinds thereof may be used in combination.

The content of the quatemary ammonium compound is preferably 0.01% to 20.0% by mass, more preferably 0.05% to 15.0% by mass, and still more preferably 0.1% to 10.0% by mass, with respect to the total mass of the cleaning liquid.

The content of the quaternary ammonium compound is preferably 0.1% to 95.0% by mass, more preferably 3.0% to 93.0% by mass, and still more preferably 5.0% to 90.0% by mass with respect to the total mass of the components in the cleaning liquid excluding the solvent.

[Organic Acid]

The cleaning liquid may contain an organic acid.

The organic acid is a compound different from the above-described compound that can be contained in the cleaning liquid. In addition, it is preferably a compound that is different from those such as surfactants and/or reductive sulfur compounds described later.

Examples of the organic acid include a carboxylic acid-based organic acid and a phosphonic acid-based organic acid, where a carboxylic acid-based organic acid is preferable.

Examples of the acid group contained in the organic acid include a carboxy group, a phosphonate group, a sulfo group, and a phenolic hydroxyl group.

The organic acid preferably has at least one selected from the group consisting of a carboxy group and a phosphonate group, and more preferably has a carboxy group.

The organic acid preferably has a low molecular weight.

Specifically, the molecular weight of the organic acid is preferably 600 or less, more preferably 450 or less, and still more preferably 300 or less. The lower limit thereof is preferably 50 or more and more preferably 100 or more.

The organic acid preferably has 1 to 15 carbon atoms and more preferably has 2 to 15 carbon atoms.

<Carboxylic Acid-Based Organic Acid>

The carboxylic acid-based organic acid means an organic acid having at least one carboxy group in the molecule.

The carboxylic acid-based organic acid is preferably a compound represented by Formula (D) and more preferably a compound represented by Formula (D1).

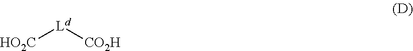

In Formula (D), L^{d} represents a single bond or a divalent linking group.

Examples of the divalent linking group include an ether group, a carbonyl group, an ester group, a thioether group, —SO₂—, -NT-, a divalent hydrocarbon group (for example, an alkylene group, an alkenylene group, an alkynylene group, or an arylene group), and a group obtained by combining these. T represents a substituent. The divalent linking group may further have a substituent.

Examples of the substituent include an alkyl group, an aryl group, a hydroxyl group, a carboxy group, an amino group, and a halogen atom, where a hydroxyl group or a carboxy group is preferable.

Among them, L^{d} is preferably a single bond or a divalent hydrocarbon group and more preferably an alkylene group which may have a substituent.

The divalent linking group preferably has 1 to 5 substituents and more preferably has 1 to 3 substituents.

The divalent linking group preferably has 1 to 15 carbon atoms, more preferably has 1 to 10 carbon atoms, and still more preferably has 1 to 5 carbon atoms.

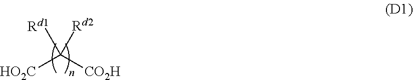

In Formula (D1), R^{d1} and R^{d2} each independently represent a hydrogen atom, a hydroxyl group, or a carboxy group. n represents an integer of 1 to 5.

The total number of hydroxyl groups contained in R^{d1} and R^{d2} is preferably 0 to 4 and more preferably 0 to 2.

The total number of carboxy groups contained in R^{d1} and R^{d2} is preferably 0 to 4, more preferably 0 to 2, and still more preferably 1.

The total number of hydroxyl groups and carboxy groups contained in R^{d1} and R^{d2} is preferably 0 to 8, more preferably 0 to 4, and still more preferably 0 to 2.

A plurality of R^{d1}'s and a plurality of R^{d2}'s may be the same or may not be the same with each other, respectively.

n represents an integer of 1 to 5.

n is preferably 1 to 4 and more preferably 1 to 3.

Examples of the carboxylic acid-based organic acid include an amino polycarboxylic acid-based organic acid, an amino acid-based organic acid, and an aliphatic carboxylic acid-based organic acid, where an aliphatic carboxylic acid-based organic acid is preferable.

Examples of the amino polycarboxylic acid-based organic acid include 1,4-butanediaminetetraacetic acid (BDTA), diethylenetriaminepentaacetic acid (DTPA), ethylenediaminetetrapropionic acid, triethylenetetraminehexacetic acid, 1,3-diamino-2-hydroxypropane-N,N,N′,N′-tetraacetic acid, 1,3-propanediamine-N,N,N′,N′-tetraacetic acid, ethylenediaminetetraacetic acid (EDTA), trans-1,2-diaminocyclohexanetetraacetic acid, ethylenediaminediacetic acid, ethylenediaminedipropionic acid, 1,6-hexamethylene-diamine-N,N,N′,N′-tetraacetic acid, N,N-bis(2-hydroxybenzyl)ethylenediamine-N,N-diacetic acid, diaminopropanetetraacetic acid, 1,4,7,10-tetraazacyclododecane-tetraacetic acid, diaminopropanoltetraacetic acid, (hydroxyethyl)ethylenediaminetriacetic acid, and iminodiacetic acid (IDA), where diethylenetriaminepentaacetic acid (DTPA) is preferable.

Examples of the amino acid-based organic acid include glycine, serine, α-alanine (2-aminopropionic acid), 0-alanine (3-aminopropionic acid), lysine, leucine, isoleucine, cystine, cysteine, ethionine, threonine, tryptophan, tyrosine, valine, histidine, a histidine derivative, asparagine, aspartic acid, glutamine, glutamic acid, arginine, proline, methionine, phenylalanine, the compounds described in paragraphs [0021] to [0023] of JP2016-086094A, and salts thereof.

Examples of the histidine derivative include the compounds described in JP2015-165561A and JP2015-165562A, the contents of which are incorporated in the present specification. In addition, examples of the salt include an alkali metal salt such as a sodium salt or a potassium salt, an ammonium salt, a carbonate, and acetate.

The aliphatic carboxylic acid-based organic acid may have a hydroxyl group in addition to the carboxylic acid group and the aliphatic group.

Examples of the aliphatic carboxylic acid-based organic acid include tartaric acid, oxalic acid, malonic acid, succinic acid, glutaric acid, adipic acid, pimelic acid, sebacic acid, maleic acid, malic acid, and citric acid.

Among them, the aliphatic carboxylic acid-based organic acid preferably includes at least one selected from the group consisting of tartaric acid, citric acid, malonic acid, and succinic acid, and more preferably includes tartaric acid.

<Phosphoric Acid-Based Organic Acid>

The phosphonic acid-based organic acid is an organic acid having at least one phosphonate group in the molecule.

It is noted that in a case where the organic acid has a phosphonate group and a carboxy group, it is classified as a carboxylic acid-based organic acid.

Examples of the phosphonic acid-based organic acid include an aliphatic phosphonic acid-based organic acid and an amino phosphonic acid-based organic acid.

The aliphatic phosphonic acid-based organic acid may further have a hydroxyl group in addition to the phosphonate group and the aliphatic group.

Examples of the phosphonic acid-based organic acid include ethylidene diphosphonic acid, 1-hydroxyethylidene-1,1′-diphosphonic acid (HEDPO), 1-hydroxypropyridene-1,1′-diphosphonic acid, and 1-hydroxybutylidene-1,1′-diphosphonic acid, ethylaminobis(methylenephosphonic acid), dodecylaminobis(methylenephosphonic acid), nitrilotris(methylenephosphonic acid) (NTPO), ethylenediaminebis(methylenephosphonic acid) (EDDPO), 1,3-propylenediaminebis(methylenephosphonic acid), ethylenediaminetetra(methylenephosphonic acid) (EDTPO), ethylenediaminetetra(ethylenephosphonic acid), 1,3-propylenediaminetetra(methylenephosphonic acid) (PDTMP), 1,2-diaminopropanetetra(methylenephosphonic acid), 1,6-hexamethylenediaminetetra(methylenephosphonic acid), diethylenetriaminepenta(methylenephosphonic acid) (DEPPO), diethylenetriaminepenta(ethylenephosphonic acid), triethylenetetraminehexa(methylenephosphonic acid), and triethylenetetraminehexa(ethylenephosphonic acid), where HEDPO or EDTPO is preferable.

The number of phosphonate groups contained in the phosphonic acid-based organic acid is preferably 2 to 5, more preferably 2 to 4, and still more preferably 2 or 3. The phosphonic acid-based organic acid preferably has 1 to 12 carbon atoms, more preferably has 1 to 10 carbon atoms, and still more preferably has 1 to 8 carbon atoms.

Examples of the phosphonic acid-based organic acid include the compounds ((co)polymers) described in paragraphs [0026] to [0036] of WO2018/020878A, and paragraphs [0031] to [0046] of WO2018/030006A, the contents of which are incorporated in the present specification.

Some commercially available phosphonic acid-based organic acids include those containing water such as distilled water, deionized water, or ultrapure water, in addition to the phosphonic acid-based organic acid; however, such a phosphonic acid-based organic acid containing water may be used.

In a case where the cleaning liquid contains a phosphonic acid-based organic acid, it is also preferable that the cleaning liquid further contains another acid (preferably, the above-described carboxylic acid-based organic acid). In this case, the mass ratio of the content of the carboxylic acid-based organic acid to the content of the phosphonic acid-based organic acid (content of carboxylic acid-based organic acid/content of phosphonic acid-based organic acid) is preferably 0.1 to 10, more preferably 0.2 to 5, and still more preferably 0.6 to 1.3.

The organic acid preferably includes at least one selected from the group consisting of an aliphatic carboxylic acid and an aliphatic phosphonic acid.

The organic acid is preferably one or more selected from the group consisting of DTPA, EDTA, trans-1,2-diaminocyclohexanetetraacetic acid, IDA, arginine, glycine, β-alanine, an aliphatic carboxylic acid-based organic acid, HEDPO, NTPO, EDTPO, DEPPO, and gluconic acid. It preferably includes at least one selected from the group consisting of tartaric acid, citric acid, malonic acid, and succinic acid, and more preferably includes tartaric acid.

One kind of the organic acid may be used alone, or two or more kinds thereof may be used in combination.

From the viewpoint that the performance of the cleaning liquid is excellent in a well-balanced, the content of the organic acid is preferably 0.01% to 10.0% by mass, more preferably 0.05% to 5.0% by mass, and still more preferably 0.1 to 5.0% by mass with respect to the total mass of the cleaning liquid.

The content of the organic acid is preferably 0.01% to 90.0% by mass, more preferably 0.1% to 55.0% by mass, and still more preferably 0.5% to 45.0% by mass with respect to the total mass of the components in the cleaning liquid excluding the solvent.

[Amino Alcohol]

The cleaning liquid may contain an amino alcohol.

The amino alcohol is a compound among the primary amines, which has at least one hydroxyl group (preferably a hydroxylalkyl group) in the molecule.

The amino alcohol is a compound different from the above-described compound that can be contained in the cleaning liquid.

The number of hydroxyalkyl groups contained in the amino alcohol is preferably 1 to 5.

The amino alcohol may include a secondary and/or a tertiary amino group as long as it is an amino alcohol (a primary amino alcohol) having at least one (for example, 1 to 5) primary amino group in the molecule. The total number of primary to tertiary amino groups contained in the amino alcohol is preferably 1 to 5.

Among the above, the amino alcohol is more preferably an amino alcohol having only a primary amino group as an amino group.

Examples of the amino alcohol include monoethanolamine (MEA), 2-amino-2-methyl-1-propanol (AMP), 2-(2-aminoethylamino)ethanol (AAE), 3-amino-1-propanol, 1-amino-2-propanol, 2-[[2-(dimethylamino)ethyl]methylamino]ethanol, N,N′-bis(2-hydroxyethyl)ethylenediamine, 1,1-((3-(dimethylamino)propylimino)-bis-2-propanol, N,N,N′-trimethylaminoethylethanolamine, trishydroxymethylaminomethane, and 2-(aminoethoxy)ethanol (AEE).

One kind of the amino alcohol may be used alone, or two or more kinds thereof may be used in combination.

From the viewpoint that the performance of the cleaning liquid is excellent in a well-balanced, the content of the amino alcohol is preferably 0.01% to 10% by mass, more preferably 0.05% to 5% by mass, and still more preferably 0.1 to 4% by mass with respect to the total mass of the cleaning liquid.

The content of the amino alcohol is preferably 0.01% to 70% by mass, more preferably 0.1% to 50% by mass, and still more preferably 1.0% to 40% by mass with respect to the total mass of the components in the cleaning liquid excluding the solvent.

[Water]

The cleaning liquid may contain water as a solvent.

Regarding the kind of water used for the cleaning liquid, distilled water, deionized water, or pure water (ultrapure water) can be used as long as it does not adversely affect a semiconductor substrate. Pure water (ultrapure water) is preferable from the viewpoint that it includes almost no impurities and has less influence on a semiconductor substrate in a step of manufacturing the semiconductor substrate.

It suffices that the content of water is the remainder of the components that can be contained in the cleaning liquid.

The content of water is preferably 1.0% by mass or more, more preferably 30.0% by mass or more, still more preferably 60.0% by mass or more, and particularly preferably 80.0% by mass or more, with respect to the total mass of the cleaning liquid. The upper limit thereof is preferably 99.99% by mass or less, more preferably 99.9% by mass or less, still more preferably 99.0% by mass or less, and particularly preferably 97.0% by mass or less, with respect to the total mass of the cleaning liquid.

[Surfactant]

The cleaning liquid may include a surfactant.

The surfactant is a compound different from the above-described compound that can be contained in the cleaning liquid.

The surfactant is a compound having a hydrophilic group and a hydrophobic group (a lipophilic group) in one molecule, and examples thereof include an anionic surfactant, a cationic surfactant, a nonionic surfactant, and an amphoteric surfactant, where a nonionic surfactant is preferable.

In a case where the cleaning liquid contains a surfactant, it is preferable from the viewpoint that the corrosion prevention performance of the metal film and the removability of the polishing fine particles are more excellent.

In a large number of cases, the surfactant has at least one hydrophobic group selected from the group consisting of an aliphatic hydrocarbon group, an aromatic hydrocarbon group, and a group obtained by combining these.

In a case where the hydrophobic group includes an aromatic hydrocarbon group, the hydrophobic group contained in the surfactant preferably has 6 or more carbon atoms and more preferably has 10 or more carbon atoms. In a case where the hydrophobic group does not includes an aromatic hydrocarbon group but consists only of an aliphatic hydrocarbon group, the hydrophobic group contained in the surfactant preferably has 9 or more carbon atoms, more preferably has 13 or more carbon atoms, and still more preferably has 16 or more carbon atoms. The upper limit thereof is preferably 20 or less and more preferably 18 or less.

The total number of carbon atoms of the surfactant is preferably 16 to 100.

(Nonionic Surfactant)

Examples of the nonionic surfactant include an ester-type nonionic surfactant, an ether-type nonionic surfactant, an ester-ether-type nonionic surfactant, and an alkanolamine-type nonionic surfactant, where an ether-type nonionic surfactant is preferable.

The nonionic surfactant preferably contains a group represented by Formula (E1).

*-(LO)ₙ* Formula (E1)

In Formula (E1), L represents an alkylene group. n represents an integer of 3 to 60. * represents a bonding position.

The alkylene group may be linear or branched.

The alkylene group preferably has 1 to 10 carbon atoms, more preferably has 2 or 3 carbon atoms, and still more preferably has 2 carbon atoms.

n is preferably 3 to 30, more preferably 6 to 20, and still more preferably 7 to 15.

In other words, examples of the group represented by Formula (E1) include polyoxyalkylene groups having a repetition number n (for example, a polyoxyethylene group, a polyoxypropylene group, and a polyoxyethylene polyoxypropylene group).

Among them, the group represented by Formula (E1) is preferably a polyoxyethylene group in which n is 3 to 30, more preferably a polyoxyethylene group in which n is 6 to 20, and still more preferably a polyoxyethylene group in which n is 7 to 15.

The group that is bonded to the terminal of the O side of the group represented by Formula (E1) (that is, the group that is bonded to the right side of the group represented by Formula (E1)) is preferably “*1-L-O-*2”. L in “*1-L-O-*2” is the same as L in Formula (E1), where *1 is a bonding position to O that is present at the terminal of the group represented by Formula (E1), and *2 is a bonding position on a side opposite to *1.

The group that is bonded to the terminal of the O side of the group represented by Formula (E1) (that is, the group that is bonded to the left side of the group represented by Formula (E1)) is preferably a hydrogen atom, an alkyl group, or an aromatic ring group which may have a substituent, and it is more preferably a hydrogen atom.

The alkyl group may be linear or branched.

The alkyl group preferably has 1 to 30 carbon atoms.

The aromatic ring group preferably has 1 to 30 carbon atoms.

Examples of the substituent contained in the aromatic ring group include a hydrocarbon group such as an alkyl group, where a hydrocarbon group having 1 to 30 carbon atoms is preferable.

The group that is bonded to the terminal of the L side of the group represented by Formula (E1) is preferably a group other than “*3-O-L-O-*3”. L in “*3-O-L-O-*3” is the same as L in Formula (E1), where *3 is a bonding position.

The group that is bonded to the terminal of the L side of the group represented by Formula (E1) is preferably a hydroxyl group, an alkoxy group, or a group represented by aromatic ring-O—, which may have a substituent, and it is more preferably a group represented by aromatic ring-O—, which may have a substituent.

The alkoxy group may be linear or branched.

The alkoxy group preferably has 1 to 30 carbon atoms and more preferably has 1 to 20 carbon atoms.

The aromatic ring group preferably has 1 to 30 carbon atoms, more preferably has 1 to 10 carbon atoms, and still more preferably has 3 to 6 carbon atoms.

In addition, examples of the substituent contained in the aromatic ring group include a hydrocarbon group such as an alkyl group, where a hydrocarbon group having 1 to 30 carbon atoms is preferable.

The nonionic surfactant more preferably contains a group represented by Formula (E2).

-Ph-O-(LO)ₙ- Formula (E2)

In Formula (E2), “(LO).” has the same meaning as the group represented by Formula (E1), and the same also applies to the suitable aspect thereof.

In Formula (E2), Ph represents a phenylene group.

In the group represented by Formula (E2), the group that is bonded at the terminal on the Ph side is preferably a hydrogen atom or an alkyl group and more preferably an alkyl group.

The alkyl group may be linear or branched.

The alkyl group preferably has 1 to 30 carbon atoms, more preferably has 1 to 20 carbon atoms, and still more preferably has 5 to 10 carbon atoms.

Examples of the nonionic surfactant include a compound represented by Formula (E).

R^{NA}-L^{NA1}-(LO)ₙ-L^{NA2}-H Formula (E)

In Formula (E), “(LO)ₙ” has the same meaning as the group represented by Formula (E1), and the same also applies to the suitable aspect thereof.

In Formula (E), R^{NA} represents an alkyl group which may have a substituent, an aryl group which may have a substituent, and a group obtained by combining these (for example, an alkylaryl group (an aryl group having a substituted alkyl group)).

Examples of the substituent include a halogen atom such as a fluorine atom and a hydroxyl group. The alkyl group may be linear or branched.

The alkyl group preferably has 1 to 30 carbon atoms and more preferably 7 to 15 carbon atoms.

The aryl group preferably has 6 to 12 carbon atoms. One or more ethylene groups in the alkyl group may be replaced with a vinylene group.

In Formula (E), L^{NA1} and L_{NA2} each independently represent a single bond or a divalent linking group. The divalent linking group is preferably —O—, —CO—, —NR¹¹—, —S—, —SO₂—, —PO(OR¹²)—, an alkylene group which may have a substituent (preferably, having 1 to 6 carbon atoms), an arylene group which may have a substituent, or a group obtained by combining these groups. It is noted that R¹¹ represents a hydrogen atom, an alkyl group, an aryl group, or an aralkyl group. R¹² represents an alkyl group, an aryl group, or an aralkyl group.

Among them, L^{NA1} is preferably —O—. L^{NA2} is preferably a single bond.

Examples of the nonionic surfactant include polyoxyalkylene alkyl ethers (for example, polyoxyethylene stearyl ether), polyoxyalkylene alkenyl ethers (for example, polyoxyethylene oleyl ether), polyoxyethylene alkyl phenyl ethers (for example, polyoxyethylene nonyl phenyl ether), polyoxyalkylene glycol (for example, polyoxypropylene polyoxyethylene glycol), polyoxyalkylene monoalkylates (monoalkyl fatty acid ester polyoxyalkylene) (for example, polyoxyethylene monoalkylates such as polyoxyethylene monostearate and polyoxyethylene monooleate), polyoxyalkylene dialkylates (dialkyl fatty acid ester polyoxyalkylene) (for example, polyoxyethylene dialkylates such as polyoxyethylene distearate and polyoxyethylene diolate), bispolyoxyalkylene alkylamides (for example, bispolyoxyethylene stearylamide), a sorbitan fatty acid ester, a polyoxyethylene sorbitan fatty acid ester, a polyoxyethylene alkylamine, a glycerin fatty acid ester, an oxyethylene oxypropylene block copolymer, an acetylene glycol-based surfactant, and an acetylene-based polyoxyethylene oxide.

Among them, the nonionic surfactant is preferably a polyoxyethylene alkyl phenyl ether.

<Anionic Surfactant>

Examples of the anionic surfactant include, as a hydrophilic group (an acid group), a phosphoric acid ester-based surfactant having a phosphoric acid ester group, a phosphonic acid-based surfactant having a phosphonate group, a sulfonic acid-based surfactant having a sulfo group, a carboxylic acid-based surfactant having a carboxy group, and a sulfuric acid ester-based surfactant having a sulfuric acid ester group.

(Phosphoric Acid Ester-Based Surfactant)

Examples of the phosphoric acid ester-based surfactant include an alkyl phosphoric acid ester, and a polyoxyalkylene alkyl ether phosphoric acid ester, as well as a salt thereof.

The phosphoric acid ester and the polyoxyalkylene alkyl ether phosphoric acid ester generally include both a monoester and a diester; however, the monoester or the diester can be used alone.

Examples of the salt of the phosphoric acid ester-based surfactant include a sodium salt, a potassium salt, an ammonium salt, and an organic amine salt.

The monovalent alkyl group contained in the alkylene phosphoric acid ester and the polyoxyalkylene alkyl ether phosphoric acid ester is preferably an alkyl group having 2 to 24 carbon atoms, more preferably an alkyl group having 6 to 18 carbon atoms, and still more preferably an alkyl group having 12 to 18 carbon atoms.

The divalent alkylene group contained in the polyoxyalkylene alkyl ether phosphoric acid ester is preferably an alkylene group having 2 to 6 carbon atoms, and more preferably an ethylene group or a 1,2-propanediyl group. In addition, the number of repetitions of the oxyalkylene group in the polyoxyalkylene ether phosphoric acid ester is preferably 1 to 12 and more preferably 1 to 6.

The phosphoric acid ester-based surfactant is preferably an octyl phosphoric acid ester, a lauryl phosphoric acid ester, a tridecyl phosphoric acid ester, a myristyl phosphoric acid ester, a cetyl phosphoric acid ester, a stearyl phosphoric acid ester, a polyoxyethylene octyl ether phosphoric acid ester, a polyoxyethylene lauryl ether phosphoric acid ester, a polyoxyethylene tridecyl ether phosphoric acid ester, or a polyoxyethylene myristyl ether phosphoric acid ester, more preferably a lauryl phosphoric acid ester, a tridecyl phosphoric acid ester, a myristyl phosphoric acid ester, a cetyl phosphoric acid ester, a stearyl phosphoric acid ester, or a polyoxyethylene myristyl ether phosphoric acid ester, and still more preferably, a lauryl phosphoric acid ester, a cetyl phosphoric acid ester, a stearyl phosphoric acid ester, or a polyoxyethylene myristyl ether phosphoric acid ester.

Examples of the phosphoric acid ester-based surfactant include the compounds described in paragraphs [0012] to [0019] of JP2011-040502A, the contents of which are incorporated in the present specification.

(Phosphonic Acid-Based Surfactant)

Examples of the phosphonic acid-based surfactant include an alkylphosphonic acid, polyvinylphosphonic acid, and the aminomethylphosphonic acid described in JP2012-057108A.

(Sulfonic Acid-Based Surfactant)

Examples of the sulfonic acid-based surfactant include an alkylsulfonic acid, an alkylbenzenesulfonic acid, an alkylnaphthalenesulfonic acid, an alkyl diphenyl ether disulfonic acid, an alkyl methyl taurine, a sulfosuccinic acid diester, a polyoxyalkylene alkyl ether sulfonic acid, and salts thereof.

The alkyl group contained in the sulfonic acid-based surfactant is preferably an alkyl group having 2 to 24 carbon atoms and more preferably an alkyl group having 6 to 18 carbon atoms.

The alkylene group contained in the polyoxyalkylene alkyl ether sulfonic acid is preferably an ethylene group or a 1,2-propanediyl group. In addition, the number of repetitions of the oxyalkylene group in the polyoxyalkylene alkyl ether sulfonic acid is preferably 1 to 12 and more preferably 1 to 6.

Examples of the sulfonic acid-based surfactant include hexanesulfonic acid, octanesulfonic acid, decanesulfonic acid, dodecanesulfonic acid, toluenesulfonic acid, cumenesulfonic acid, octylbenzenesulfonic acid, dodecylbenzenesulfonic acid (DBSA), dinitrobenzenesulfonic acid (DNBSA), and lauryldodecylphenyl ether disulfonic acid (LDPEDSA), where dodecanesulfonic acid, DBSA, DNBSA, or LDPEDSA is preferable, and DBSA, DNBSA, or LDPEDSA is more preferable.

(Carboxylic Acid-Based Surfactant)

Examples of the carboxylic acid-based surfactant include an alkylcarboxylic acid, an alkylbenzenecarboxylic acid, a polyoxyalkylene alkyl ether carboxylic acid, and salts thereof.

The alkyl group contained in the carboxylic acid-based surfactant is preferably an alkyl group having 7 to 25 carbon atoms and more preferably an alkyl group having 11 to 17 carbon atoms.

In addition, the alkylene group contained in the polyoxyalkylene alkyl ether carboxylic acid is preferably an ethylene group or a 1,2-propanediyl group. In addition, the number of repetitions of the oxyalkylene group in the polyoxyalkylene alkyl ether carboxylic acid is preferably 1 to 12 and more preferably 1 to 6.

Examples of the carboxylic acid-based surfactant include lauric acid, myristic acid, palmitic acid, stearic acid, polyoxyethylene lauryl ether acetic acid, and polyoxyethylene tridecyl ether acetic acid.

(Sulfuric Acid Ester-Based Surfactant)

Examples of the sulfuric acid ester-based surfactant include an alkyl sulfuric acid ester and a polyoxyalkylene alkyl ether sulfuric acid ester, as well as salts thereof.

The alkyl group contained in the alkyl sulfuric acid ester and the polyoxyalkylene alkyl ether sulfuric acid ester is preferably an alkyl group having 2 to 24 carbon atoms, and more preferably an alkyl group having 6 to 18 carbon atoms.

The alkylene group contained in the polyoxyalkylene alkyl ether sulfuric acid ester is preferably an ethylene group or a 1,2-propanediyl group. In addition, the number of repetitions of the oxyalkylene group in the polyoxyalkylene alkyl ether sulfuric acid ester is preferably 1 to 12 and more preferably 1 to 6.

Examples of the sulfuric acid ester-based surfactant include a lauryl sulfuric acid ester, a myristyl sulfuric acid ester, and a polyoxyethylene lauryl ether sulfuric acid ester.

Examples of the surfactant include the compounds described in paragraphs [0092] to [0096] of JP2015-158662A, paragraphs [0045] and [0046] of JP2012-151273A, and paragraphs [0014] to [0020] of JP2009-147389A, the contents of which are incorporated in the present specification.

One kind of the surfactant may be used alone, or two or more kinds thereof may be used in combination.

From the viewpoint that the performance of the cleaning liquid is excellent in a well-balanced, the content of the surfactant is preferably 0.001% to 8.0% by mass, more preferably 0.005% to 5.0% by mass, and still more preferably 0.01 to 3.0% by mass, with respect to the total mass of the cleaning liquid.

From the viewpoint that the performance of the cleaning liquid is excellent in a well-balanced manner, the content of the surfactant is preferably 0.01% to 50.0% by mass, more preferably 0.10% to 45.0% by mass, still more preferably 0.7% to 40.0% by mass, and particularly preferably 0.7% to 10.0% by mass, with respect to the total mass of the components in the cleaning liquid excluding the solvent.

[Azole Compound]

The cleaning liquid may contain an azole compound.

The azole compound is a compound different from the above-described compound that can be contained in the cleaning liquid.

The azole compound is an aromatic compound having a hetero-5-membered ring that contains at least one nitrogen atom.

The azole compound can improve the corrosion preventing action of the cleaning liquid. That is, the azole compound can act as an anticorrosion agent.

The number of nitrogen atoms contained in the hetero-5-membered ring of the azole compound is preferably 1 to 4 and more preferably 1 to 3.

The azole compound may have a substituent on the hetero 5-membered ring.

Examples of the substituent include a hydroxyl group, a carboxy group, a mercapto group, an amino group, an alkyl group having 1 to 4 carbon atoms, which may have an amino group, and a 2-imidazolyl group.

Examples of the azole compound include an imidazole compound in which one of the atoms constituting the azole ring is a nitrogen atom, a pyrazole compound in which two of the atoms constituting an azole ring are nitrogen atoms, and a thiazole compound in which one of the atoms constituting an azole ring is a nitrogen atom and the other is a sulfur atom, a triazole compound in which three of the atoms constituting an azole ring are nitrogen atoms, and a tetrazole compound in which four of the atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, and benzoimidazole.

Examples of the pyrazole compound include pyrazole, 4-pyrazolecarboxylic acid, 1-methylpyrazole, 3-methylpyrazole, 3-amino-5-methylpyrazole, 3-amino-5-hydroxypyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, 5-methylbenzotriazole, and 2,2′-{[(5-methyl-1H-benzotriazole-1-yl)methyl]imino}diethanol.

Examples of the tetrazole compound include 1H-tetrazole (1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

The azole compound is preferably a triazole compound, an imidazole compound, or a pyrazole compound, and it is more preferably a triazole compound, pyrazole, or 3-amino-5-methylpyrazole.

One kind of the azole compound may be used alone, or two or more kinds thereof may be used in combination.

The content of the azole compound is preferably 0.01% to 10% by mass, more preferably 0.05% to 5% by mass, and still more preferably 0.1% to 4% by mass, with respect to the total mass of the cleaning liquid.

The content of the azole compound is preferably 0.01% to 95% by mass, more preferably 0.1% to 85% by mass, and still more preferably 1.0% to 80% by mass with respect to the total mass of the components in the cleaning liquid excluding the solvent.

[Polyhydroxy Compound Having Molecular Weight of 500 or More]

The cleaning liquid may include a polyhydroxy compound having a molecular weight of 500 or more.

The polyhydroxy compound is a compound different from the above-described compound that can be contained in the cleaning liquid.

The polyhydroxy compound is an organic compound having two or more (for example, 2 to 200) alcoholic hydroxyl groups in one molecule.

The molecular weight (the weight-average molecular weight in a case of having a molecular weight distribution) of the polyhydroxy compound is 500 or more, and it is preferably 500 to 100,000 and more preferably 500 to 3,000.

Examples of the polyhydroxy compound include polyoxyalkylene glycols such as polyethylene glycol, polypropylene glycol, and polyoxyethylene polyoxypropylene glycol; oligosaccharides such as manninotriose, cellotriose, gentianose, raffinose, melezitose, cellotetrose, and stachyose; and polysaccharides such as starch, glycogen, cellulose, chitin, and chitosan, and hydrolysates thereof.

It is also preferable that the polyhydroxy compound is cyclodextrin.

The cyclodextrin means one kind of cyclic oligosaccharide having a cyclic structure in which a plurality of D-glucoses are bonded by a glucoside bond. A compound in which 5 or more (for example, 6 to 8) glucoses are bonded is known.

Examples of the cyclodextrin include α-cyclodextrin, β-cyclodextrin, and γ-cyclodextrin, where γ-cyclodextrin is preferable.

One kind of the polyhydroxy compound may be used alone, or two or more kinds thereof may be used in combination.

The content of the polyhydroxy compound is preferably 0.010% to 10% by mass, more preferably 0.05% to 5% by mass, and still more preferably 0.1% to 3% by mass, with respect to the total mass of the cleaning liquid.

The content of the polyhydroxy compound is preferably 0.01% to 30% by mass, more preferably 0.05% to 25% by mass, and still more preferably 0.5% to 20% by mass with respect to the total mass of the components of the cleaning liquid excluding the solvent.

[Reductive Sulfur Compound]

The cleaning liquid may contain a reductive sulfur compound.

The reductive sulfur compound is a compound different from the above-described compound that can be contained in the cleaning liquid.

The reductive sulfur compound is a compound that has reducing properties and contains a sulfur atom.

The reductive sulfur compound can improve the corrosion preventing action of the cleaning liquid. That is, the reductive sulfur compound can act as an anticorrosion agent.

Examples of the reductive sulfur compound include 3-mercapto-1,2,4-triazole, mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

Among them, a compound having an SH group (mercapto compound) is preferable, and 1-thioglycerol, sodium 3-mercapto-1-propanesulfonate, 2-mercaptoethanol, 3-mercapto-1-propanol, or thioglycolic acid is more preferable.

One kind of the reductive sulfur compound may be used alone, or two or more kinds thereof may be used in combination.

The content of the reductive sulfur compound is preferably 0.01% to 10% by mass, more preferably 0.05% to 5% by mass, and still more preferably 0.1% to 3% by mass, with respect to the total mass of the cleaning liquid.

The content of the reductive sulfur compound is preferably 0.01% to 30.0% by mass, more preferably 0.05% to 25.0% by mass, and still more preferably 0.5% to 20.0% by mass with respect to the total mass of the components in the cleaning liquid excluding the solvent.

[Polymer]

The cleaning liquid may include a polymer.

The polymer is a compound different from the above-described compound that can be contained in the cleaning liquid.

It is also preferable that the polymer is a water-soluble polymer.

The “water-soluble polymer” means a compound having two or more constitutional units linked in a linear or mesh form through a covalent bond, in which the mass of the polymer dissolved in 100 g of water at 20° C. is 0.1 g or more.

Examples of the water-soluble polymer include a polyacrylic acid, a polymethacrylic acid, a polymaleic acid, a polyvinylsulfonic acid, a polyallylsulfonic acid, a polystyrenesulfonic acid, and salts thereof, copolymers of monomers such as styrene, α-methylstyrene, and/or 4-methylstyrene and acid monomers such as a (meth)acrylic acid and/or a maleic acid, and salts thereof, polymers having constitutional units having an aromatic hydrocarbon group obtained by fusing benzenesulfonic acid and/or naphthalenesulfonic acid, and the like with formalin; polyglycerin; vinyl-based synthetic polymers such as polyvinyl alcohol, polyoxyethylene, polyvinylpyrrolidone, polyvinylpyridine, polyacrylamide, polyvinyl formamide, polyethyleneimine, polyvinyloxazoline, polyvinylimidazole, and polyallylamine; and modified products of natural polysaccharides such as hydroxyethyl cellulose, carboxymethyl cellulose, and processed starch.

The water-soluble polymer may be a homopolymer or a copolymer obtained by copolymerizing two or more kinds of monomers.

Examples of such a monomer include a monomer selected from the group consisting of a monomer having a carboxylic acid group, a monomer having a sulfonic acid group, a monomer having a hydroxyl group, a monomer having a polyethylene oxide chain, a monomer having an amino group, and a monomer having a heterocyclic ring.

It is also preferable that the water-soluble polymer is a polymer consisting of only structural units derived from the monomers selected from the group. In a case where the polymer is composed of substantially only a structural unit derived from the monomer selected from the group, for example, the content of the structural unit derived from the monomer selected from the group is preferably 95% to 100% by mass and more preferably 99% to 100% by mass with respect to the total mass of the polymer used.

In addition, examples of the polymer also include the water-soluble polymers described in paragraphs [0043] to [0047] of JP2016-171294A, the contents of which are incorporated in the present specification.

The molecular weight (the weight-average molecular weight in a case of having a molecular weight distribution) of the polymer is preferably 300 or more, more preferably more than 600, still more preferably 1,000 or more, particularly preferably more than 1,000, and most preferably 2,000 or more. The upper limit thereof is preferably 1,500,000 or less and more preferably 1,000,000 or less.

Among them, in a case where the polymer is a water-soluble polymer which will be described below, the weight-average molecular weight of the water-soluble polymer is preferably 300 or more, more preferably 1,000 or more, still more preferably 1,500 or more, and particularly preferably 2,000 or more. The upper limit thereof is preferably 1,500,000 or less, more preferably 1,200,000 or less, and still more preferably 1,000,000 or less.

The polymer preferably has a constitutional unit having a carboxy group (a constitutional unit derived from (meth)acrylic acid, or the like). The content of the constitutional unit having a carboxy group is preferably 30% to 100% by mass, more preferably 70% to 100% by mass, and still more preferably 85% to 100% by mass with respect to the total mass of the polymer.

One kind of the polymer may be used alone, or two or more kinds thereof may be used in combination.

The content of the polymer is preferably 0.01% to 10% by mass, more preferably 0.05% to 5% by mass, and still more preferably 0.1% to 3% by mass, with respect to the total mass of the cleaning liquid.

The content of the polymer is preferably 1% to 50% by mass, more preferably 2% to 35% by mass, and still more preferably 5% to 25% by mass with respect to the total mass of the components in the cleaning liquid excluding the solvent.

In a case where the content of the polymer is within the range, the polymer can be appropriately adsorbed on a surface of a substrate to contribute to the improvement of the corrosion prevention performance of the cleaning liquid, and a balance with the viscosity and/or the cleaning performance of the cleaning liquid is also excellent.

[Oxidizing Agent]

The cleaning liquid may include an oxidizing agent.

The oxidizing agent is a compound different from the above-described compound that can be contained in the cleaning liquid.

Examples of the oxidizing agent include a peroxide, a persulfide (for example, a monopersulfide or a dipersulfide), a percarbonate, or an acid thereof or a salt thereof.

Examples of the oxidizing agent include an oxidative halide (a periodic acid such as iodic acid, metaperiodic acid, or orthoperiodic acid, or a salt thereof), a perboric acid, a perboric acid salt, a cerium compound, and a ferricyanide (potassium ferricyanide or the like).

The content of the oxidizing agent is preferably 0.01% to 10.0% by mass, more preferably 0.05% to 5.0% by mass, and still more preferably 0.1% to 3.0% by mass, with respect to the total mass of the cleaning liquid.

The content of the oxidizing agent is preferably 5.0% to 60.0% by mass, more preferably 10.0% to 50.0% by mass, and still more preferably 10.0% to 40.0% by mass with respect to the total mass of the components in the cleaning liquid excluding the solvent.

[Another Amine Compound]

The cleaning liquid may contain another amine compound.

The other amine compound is a compound different from the above-described compound that can be contained in the cleaning liquid. Specifically, as an example, the aliphatic tertiary amine compound is a compound different from the compound A.

The other amine compound is preferably an alicyclic amine compound, an aliphatic amine compound, or a hydrazine compound, and more preferably an aliphatic tertiary amine compound. In addition, examples of the other amine compound include a hydrazide compound.

The alicyclic amine compound is not particularly limited as long as it is a compound having a non-aromatic heterocyclic ring in which at least one of the atoms constituting the ring is a nitrogen atom.

Examples of the alicyclic amine compound include a piperazine compound and a cyclic amidine compound.

The piperazine compound is a compound having a hetero-6-membered ring (a piperazine ring) in which the opposite —CH— group of a cyclohexane ring is replaced with a nitrogen atom.

The piperazine compound may have a substituent on the piperazine ring.

Examples of the substituent include a hydroxyl group, an alkyl group having 1 to 4 carbon atoms, which may have a hydroxyl group, and an aryl group having 6 to 10 carbon atoms. The substituents may be bonded to each other.

Examples of the piperazine compound include piperazine, 1-methylpiperazine, 1-ethylpiperazine, 1-propylpiperazine, 1-butylpiperazine, 2-methylpiperazine, 1,4-dimethylpiperazine, 2,5-dimethylpiperazine, 2,6-dimethylpiperazine, 1-phenylpiperazine, 2-hydroxypiperazine, 2-hydroxymethylpiperazine, 1-(2-hydroxyethyl)piperazine (HEP), N-(2-aminoethyl)piperazine (AEP), 1,4-bis(2-hydroxyethyl)piperazine (BHEP), 1,4-bis(2-aminoethyl)piperazine (BAEP), 1,4-bis(3-aminopropyl)piperazine (BAPP), N-methyl-N′-(2-dimethylaminoethyl)piperazine, N,N′,N″-tris(3-dimethylaminopropyl)-hexahydro-s-triazine, and 1,4-diazabicyclo[2.2.2]octane (DABCO).

The cyclic amidine compound is a compound having a heterocyclic ring including an amidine structure (>N—C═N—) in the ring.

The number of ring members of the heterocyclic ring contained in the cyclic amidine compound is preferably 5 or 6 and more preferably 6.

Examples of the cyclic amidine compound include diazabicycloundecene (1,8-diazabicyclo[5.4.0]undec-7-ene: DBU), diazabicyclononene (1,5-diazabicyclo[4.3.0]nona-5-ene: DBN), 3,4,6,7,8,9,10,11-octahydro-2H-pyrimid[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimid[1.2-a]azepine, and creatinine.

Examples of the alicyclic amine compound include, in addition to those described above, a compound having a hetero 5-membered ring having no aromaticity, such as 1,3-dimethyl-2-imidazolidinone or imidazolidinethione, a compound having a 6-membered ring containing an oxygen atom, such as morpholine (for example, N-(2-hydroxyethylmorpholine or 4-(2-cyanoethyl)morpholine), and a compound having a 7-membered ring containing a nitrogen atom.

Examples of the aliphatic amine compound include an aliphatic primary amine compound (an aliphatic amine compound having a primary amino group) an aliphatic secondary amine compound (an aliphatic amine compound having a secondary amino group, and an aliphatic tertiary amine compound (an aliphatic amine compound having a tertiary amino group), where an aliphatic tertiary amine compound is preferable from the viewpoint that the effect of the present invention is more excellent.

It is noted that the aliphatic amine compound may have amino groups of different classes.

In the present specification, in a case where an aliphatic amine compound has a plurality of amino groups, the aliphatic amine compound is classified into an aliphatic primary to tertiary amine compound based on the highest amino group contained in the aliphatic amine compound. Specifically, diethylenetriamine is a compound having a primary amino group and a secondary amino group, and diethylenetriamine is classified into an aliphatic secondary amine compound since the highest amino group is a secondary amino group.

Examples of the aliphatic primary amine compound include methylamine, ethylamine, propylamine, dimethylamine, diethylamine, n-butylamine, 3-methoxypropylamine, tert-butylamine, n-hexylamine, n-octylamine, and 2-ethylhexylamine.

Examples of the aliphatic secondary amine compound include alkylenediamines such as ethylenediamine (EDA), 1,3-propanediamine (PDA), 1,2-propanediamine, 1,3-butanediamine, and 1,4-butanediamine, and polyalkylpolyamines such as diethylenetriamine (DETA), triethylenetetramine (TETA), bis(aminopropyl)ethylenediamine (BAPEDA), and tetraethylenepentamine.

Examples of the aliphatic tertiary amine compound include an aliphatic tertiary amine compound that has a tertiary amino group in the molecule but does not have an aromatic ring group.

In addition, a part of the methylene group (—CH₂—) in the aliphatic tertiary amine compound may be replaced with a heteroatom (for example, an oxygen atom or a sulfur atom).

The aliphatic tertiary amine compound preferably has two or more nitrogen atoms, and more preferably has two or more tertiary amino groups.

Examples of the aliphatic tertiary amine compound include a tertiary alkylamine compound such as trimethylamine or triethylamine, an alkylenediamine compound such as 3-(dimethylamino)propylamine or 1,3-bis(dimethylamino)butane, and a polyalkylpolyamine compound such as bis(2-dimethylaminoethyl)ether, N,N,N′,N′-tetramethylethylenediamine, N,N,N′,N′-tetramethylhexamethylenediamine, N,N,N′,N″,N′″,N′″-hexamethyltriethylenetetramine, and N,N,N′,N″,N″-pentamethyldiethylenetriamine, where N,N,N′,N″,N″-pentamethyldiethylenetriamine is preferable.

Examples of the hydrazine compound include hydrazine and a salt thereof, where hydrazine is preferable.

Examples of the hydrazine salt include a hydrochloride, a hydrobromide, and a carbonate.

Examples of the hydrazide compound and a salt thereof include adipic acid dihydrazide, sebacic acid dihydrazide, dodecanedioic dihydrazide, isophthalic acid dihydrazide, salicylic acid hydrazide, and salts thereof.

In addition, the other amine compound is also preferably an amine compound having a pKa of 8 or more.

The pKa is preferably 8.5 or more, more preferably 10 or more, and still more preferably 11 or more. The upper limit thereof is preferably 20 or less and more preferably 15 or less.

Examples of the amine compound having a pKa of 8 or more include a compound having an imino group (>C═NR or —C—NH—, where R represents a hydrogen atom or a substituent), and specific examples thereof include guanidine and a guanidine derivative (for example, 1,1,3,3-tetramethylguanidine); a cyclic amidine compound such as 1,4-diazabicyclo[2.2.2]octane, diazabicycloundecene, or diazabicyclononene; and a compound having a 6-membered ring containing an oxygen atom, such as morpholine.

The amine compound having a pKa of 8 or more preferably contains at least one compound selected from the group consisting of guanidine, a guanidine derivative, and a cyclic amidine compound, and it more preferably contains at least one compound selected from the group consisting of 1,1,3,3-tetramethylguanidine and diazabicycloundecene.

The pKa can be measured by using a known method such as neutralization titration, absorption spectrophotometry, or capillary electrophoresis.

In a case where the cleaning liquid contains the amine compound having a pKa of 8 or more, the cleaning liquid may further contain a quaternary ammonium compound or may not contain a quaternary ammonium compound. That is, the amine compound having a pKa of 8 or more can also be used as a substitute for the quaternary ammonium compound.

Examples of the other amine compound also include the organic amine compounds described in paragraphs [0019] to [0027] of JP2014-037585A, where the organic amine compounds are different from the above-described components, the contents of which are incorporated in the present specification.

One kind of the other amine compound may be used alone, or two or more kinds thereof may be used in combination.

The content of the other amine compound is preferably 0.01% to 10% by mass, more preferably 0.05% to 5% by mass, and still more preferably 0.1% to 4% by mass, with respect to the total mass of the cleaning liquid.

The content of the other amine compound is preferably 0.01% to 70% by mass, more preferably 0.1% to 50% by mass, and still more preferably 1.0% to 40% by mass with respect to the total mass of the components in the cleaning liquid excluding the solvent.

[pH Adjusting Agent]

The cleaning liquid may include a pH adjusting agent to adjust and maintain the pH of the cleaning liquid.

The pH adjusting agent is a basic compound or an acidic compound, which is different from the above-described compound that can be contained in the cleaning liquid. However, it is permissible to adjust the pH of the cleaning liquid by adjusting the adding amount of each of the above-described components.

Examples of the basic compound include a basic organic compound and a basic inorganic compound.

Examples of the basic organic compound include amine oxides, nitro compounds, nitroso compounds, oximes, ketooximes, aldoximes, lactams, isocyanides, and urea.

Examples of the basic inorganic compound include an alkali metal hydroxide, an alkaline earth metal hydroxide, and ammonia.

Examples of the alkali metal hydroxide include lithium hydroxide, sodium hydroxide, potassium hydroxide, and cesium hydroxide. Examples of the alkaline earth metal hydroxide include calcium hydroxide, strontium hydroxide, and barium hydroxide.

Examples of the acidic compound include an inorganic acid.

Examples of the inorganic acid include hydrochloric acid, sulfuric acid, sulfurous acid, nitric acid, nitrite, phosphoric acid, boric acid, and hexafluorophosphoric acid. In addition, a salt of the inorganic acid may be used, and examples thereof include an ammonium salt of the inorganic acid, and more specifically, ammonium chloride, ammonium sulfate, ammonium sulfite, ammonium nitrate, ammonium nitrite, ammonium phosphate, ammonium borate, and ammonium hexafluoride phosphate.

As the acidic compound, a salt of the acidic compound may be used as long as it is an acid or an acid ion (anion) in an aqueous solution.

The pH adjusting agent may be used alone or may be used in a combination of two or more kinds thereof.

The content of the pH adjusting agent can be selected according to the kinds and amounts of other components and the pH of the target cleaning liquid. For example, with respect to the total mass of the cleaning liquid, the content of the pH adjusting agent is preferably 0.01% to 10% by mass and more preferably 0.1% to 8% by mass with respect to the total mass of the cleaning liquid.

The content of the pH adjusting agent is preferably 0.01% to 80% by mass and more preferably 0.1% to 60% by mass with respect to the total mass of the components in the cleaning liquid excluding the solvent.

The cleaning liquid may contain a fluorine compound and/or an organic solvent in addition to the above-described compound.

Examples of the fluorine compound include the compounds described in paragraphs [0013] to [0015] of JP2005-150236A, the contents of which are incorporated in the present specification.

As the organic solvent, any one of the known organic solvents can be used, where a hydrophilic organic solvent such as an alcohol or a ketone is preferable. The organic solvent may be used alone or in a combination of two or more kinds thereof.

The using amounts of the fluorine compound and the organic solvent may be appropriately set within a range where the effect of the present invention is not impaired.

It is noted that the content of each of the above-described components in the cleaning liquid can be measured according to a known method such as gas chromatography-mass spectrometry (GC-MS), liquid chromatography-mass spectrometry (LC-MS), or ion-exchange chromatography (IC).

[Physical Properties of Cleaning Liquid]

<pH>

The cleaning liquid may be alkaline or acidic.

From the viewpoint that the performance of the cleaning liquid is excellent in a well-balanced manner, the pH of the cleaning liquid is preferably 8.0 to 14.0, more preferably 9.0 to 13.5, still more preferably 9.5 to 13.0, and particularly preferably 10.0 to 13.0. The pH of the cleaning liquid means the pH of the cleaning liquid which is not diluted.

In a case where the cleaning liquid is diluted to be used, the pH of the diluted cleaning liquid is preferably 7.5 to 14.0, more preferably 8.0 to 13.5, still more preferably 9.0 to 13.0, and particularly preferably 9.5 to 13.0.

The pH of the cleaning liquid can be measured by a method based on JIS Z8802-1984, using a known pH meter. The measurement temperature of the pH is 25° C.

<Metal Content>

In the cleaning liquid, the content (measured as the ion concentration) of metals (metal elements of Fe, Co, Na, Cu, Mg, Mn, Li, Al, Cr, Ni, Zn, Sn, and Ag) contained as impurities in the liquid is preferably 5 ppm by mass or less and more preferably 1 ppm by mass or less. In a view that high-purity cleaning liquids are further demanded in the manufacture of state-of-the-art semiconductor elements, the content of the metal is still more preferably a value of less than 1 ppm by mass, that is, a mass of ppb order or less, and particularly preferably 100 ppb by mass or less, and most preferably less than 10 ppb by mass. The lower limit thereof is preferably 0.

Examples of a method for reducing the metal content include carrying out a purifcation treatment such as distillation and filtration using an ion exchange resin or a filter at a stage of raw materials used in the production of the cleaning liquid or a stage after the production of the cleaning liquid.

Other examples of the method for reducing the metal content include using a container with less elution of impurities, which will be described later as a container that accommodates the raw material or the produced cleaning liquid. In addition, other examples of the method include lining an inner wall of a pipe with a fluororesin so that the metal component does not elute from the pipe and the like during the production of the cleaning liquid.

<Coarse Particle>

The cleaning liquid may include coarse particles, but the content of the cleaning liquid is preferably low.

The coarse particles mean particles having a diameter (particle diameter) of 0.03 μm or more in a case where the shape of the particles is regarded as a sphere.

As for the content of the coarse particles in the cleaning liquid, the content of the particles having a particle diameter of 0.1 μm or more is preferably 10,000 or less, and more preferably 5,000 or less per 1 mL of the cleaning liquid. The lower limit thereof is preferably 0 or more and more preferably 0.01 or more per 1 mL of the cleaning liquid.

The coarse particles contained in the cleaning liquid correspond to particles of dirt, dust, organic solids, inorganic solids, and the like contained as impurities in raw materials, and particles of dirt, dust, and organic solids, and inorganic solids brought in as contaminants during the preparation of the cleaning liquid, in which the particles are finally present as particles without being dissolved in the cleaning liquid.

The content of the coarse particles present in the cleaning liquid can be measured in a liquid phase by using a commercially available measuring device in a light scattering type liquid particle measuring method using a laser as a light source.

Examples of a method for removing the coarse particles include a purification treatment such as filtering which will be described later.

<Electric Conductivity>

The electrical conductivity of the cleaning liquid is preferably 0.06 to 500 mS/cm, more preferably 0.07 to 300 mS/cm, and still more preferably 0.08 to 100 mS/cm. The electric conductivity is an electric conductivity (mS/cm) which is measured using an electric conductivity meter (conductivity meter (electric conductivity meter): Portable Type D-70/ES-70 series, manufactured by HORIBA, Ltd.).

Examples of the method of adjusting the electrical conductivity include a method of adjusting the kind and content of the above-described compound that may be contained in the cleaning liquid.

[Production of Cleaning Liquid]

The cleaning liquid can be produced by a known method. Hereinafter, a method for producing the cleaning liquid will be described in detail.

<Liquid Preparation Step>

Regarding a liquid preparation method for a cleaning liquid, it is possible to produce a cleaning liquid, for example, by mixing the above-described respective components.

Regarding the order and/or the timing of mixing the above-described respective components, the preparation method includes, for example, a method in which the purine compound, the compound A, the quaternary ammonium compound, and/or the organic acid are added sequentially to a container to which purified pure water has been added, and then mixed with stirring while a pH adjusting agent is added to the mixture to adjust the pH of the mixed solution, thereby carrying out the preparation. In addition, in a case where water and the respective components are added to the container, they may be added all at once or dividedly a plurality of times.

As a stirring device and a stirring method, which are used in the preparation of the cleaning liquid, a known device may be used as a stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

The mixing of the respective components in the liquid preparation step for the cleaning liquid, and a purification treatment which will be described later, and the storage of the produced cleaning liquid are preferably carried out at a temperature of 40° C. or lower and more preferably at 30° C. or lower. In addition, the lower limit thereof is preferably 5° C. or higher, and more preferably 10° C. or higher. In a case of preparing, treating, and/or storing the cleaning liquid in the temperature range, it is possible to maintain stable performance for a long period of time.

(Purification Treatment)

It is preferable to subject any one or more of the raw materials for preparing the cleaning liquid to a purification treatment in advance. Examples of the purification treatment include known methods such as distillation, ion exchange, and filtration (filtering).

Regarding the degree of purification, it is preferable to carry out the purification until the purity of the raw material is 99% by mass or more, and it is more preferable to carry out the purification until the purity of the stock solution is 99.9% by mass or more.

Examples of the method for the purification treatment include a method of passing a raw material through an ion exchange resin, a reverse osmosis membrane (a RO membrane), or the like, distillation of a raw material, and filtering described later.

As the purification treatment, a plurality of the above-described purification methods may be combined and carried out. For example, the raw materials are subjected to primary purification by passing through an RO membrane, and then subjected to secondary purification by passing through a purification device consisting of a cation exchange resin, an anion exchange resin, or a mixed bed type ion exchange resin.

In addition, the purification treatment may be carried out a plurality of times.

(Filtering)

The filter that is used in filtering is not particularly limited as long as it is a filter that is used in a use application for filtering and the like in the related art. Examples thereof include a filter consisting of a fluororesin such as polytetrafluoroethylene (PTFE) and a tetrafluoroethylene-perfluoroalkyl vinyl ether copolymer (PFA), a polyamide-based resin such as nylon, and a polyolefin resin (including a high-density polyolefin and an ultrahigh-molecular-weight polyolefin) such as polyethylene and polypropylene (PP). Among these materials, a material selected from the group consisting of the polyethylene, the polypropylene (including a high-density polypropylene), the fluororesin (including PTFE and PFA), and the polyamide-based resin (including nylon) is preferable, and among these, the filter with the fluororesin is more preferable. In a case of carrying out filtering of the raw materials using a filter formed with these materials, it is possible to effectively remove high-polarity foreign matters which are likely to cause defects.

The critical surface tension of the filter is preferably 70 to 95 mN/m and more preferably 75 to 85 mN/m. It is noted that the value of the critical surface tension of the filter is a nominal value of a manufacturer. In a case of using a filter having a critical surface tension in the range, it is possible to effectively remove high-polarity foreign matters which are likely to cause defects.

The pore diameter of the filter is preferably 2 to 20 nm and more preferably 2 to 15 nm. By adjusting the pore diameter of the filter to be in the range, it is possible to reliably remove fine foreign matters such as impurities and aggregates included in the raw materials while suppressing clogging in filtering. With regard to the pore diameters herein, reference can be made to nominal values of filter manufacturers.

Filtering may be carried out only once or twice or more. In a case where filtering is carried out twice or more, the filters used may be the same as or different from each other.

Moreover, the filtering is preferably carried out at room temperature (25° C.) or lower, more preferably carried out at 23° C. or lower, and still more preferably carried out at 20° C. or lower. In addition, the temperature is preferably 0° C. or higher, more preferably 5° C. or higher, and still more preferably 10° C. or higher. In a case of carrying out filtering in the temperature range, it is possible to reduce the amounts of particulate foreign matter and impurities dissolved in the raw material and efficiently remove the foreign matter and impurities.

(Container)

The cleaning liquid (including the aspect of the kit or a diluted cleaning liquid described later) can be filled in any container and stored, transported, and used as long as corrosiveness does not become a problem.

In the use application for a semiconductor, the container is preferably a container which has a high degree of cleanliness inside the container and in which the elution of impurities from an inner wall of an accommodating portion of the container into each liquid is suppressed. Examples of such a container include various containers commercially available as a container for a semiconductor cleaning liquid, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container for accommodating the cleaning liquid, a container in which a liquid contact portion with each liquid, such as an inner wall of the accommodating portion, is formed from a fluororesin (perfluororesin) or a metal which has been subjected to rust prevention and metal elution prevention treatments is preferable.

The inner wall of the container is preferably formed from one or more resins selected from the group consisting of a polyethylene resin, a polypropylene resin, and a polyethylene-polypropylene resin, another resin different from these resins, and a metal which has been subjected to rust prevention and metal elution prevention treatments, such as stainless steel, Hastelloy, Inconel, and Monel.

The other resin described above is preferably a fluororesin (perfluororesin). In this manner, by using a container having an inner wall formed of a fluororesin, the occurrence of a problem of elution of ethylene or propylene oligomers can be suppressed, as compared with a container having an inner wall formed of a polyethylene resin, a polypropylene resin, or a polyethylene-polypropylene resin.

Examples of such a container having an inner wall which is a fluororesin include a FluoroPure PFA composite drum manufactured by Entegris Inc. In addition, the containers described on page 4 of JP1991-502677A (JP-H3-502677A), page 3 of WO2004/016526A, and pages 9 and 16 of WO99/46309A can also be used.

Further, for the inner wall of the container, quartz and an electropolished metal material (that is, a completely electropolished metal material) are also preferably used, in addition to the above-described fluororesin.

The metal material that is used for producing the electropolished metal material is preferably a metal material which includes at least one selected from the group consisting of chromium and nickel, and has a total content of chromium and nickel of more than 25% by mass with respect to the total mass of the metal material, and examples thereof include stainless steel and a nickel-chromium alloy.

The total content of chromium and nickel in the metal material is more preferably 30% by mass or more with respect to the total mass of the metal material.

In addition, the upper limit of the total content of Cr and Ni in the metal material is generally preferably 90% by mass or less.

As a method for electropolishing the metal material, the known method can be used. For example, the methods described in paragraphs [0011] to [0014] of JP2015-227501A, paragraphs [0036] to [0042] of JP2008-264929A, or the like can be used.

The inside of these containers is preferably cleaned before the cleaning liquid is filled. For the liquid used for the cleaning, the amount of the metal impurities in the liquid is preferably reduced. The cleaning liquid may be bottled in a container such as a gallon bottle and a coated bottle after the production, and then may be transported and stored.

In order to prevent the change in the components in the cleaning liquid during the storage, the inside of the container may be replaced with inert gas (nitrogen, argon, or the like) with a purity of 99.99995% by volume or more. In particular, a gas having a low moisture content is preferable. In addition, during the transportation and the storage, the temperature may be normal temperature or may be controlled in a range of −20° C. to 20° C. to prevent deterioration.

(Clean Room)

It is preferable that the handling including the production of the cleaning liquid, the opening and cleaning of a container, the filling of the cleaning liquid, and the like, the treatment analysis, and the measurement are all carried out in a clean room. It is preferable that the clean room satisfies 14644-1 clean room standards. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

<Diluting Step>

After undergoing a diluting step of carrying out dilution with a diluent such as water, the cleaning liquid may be used for cleaning a semiconductor substrate as a cleaning liquid (a diluted cleaning liquid) which has been diluted.

It is noted that the diluted cleaning liquid is also a form of the cleaning liquid according to the embodiment of the present invention as long as the requirements of the present invention are satisfied.

The dilution ratio of the cleaning liquid in the diluting step may be appropriately adjusted according to the kind and the content of each component, the semiconductor substrate as an object to be cleaned. However, the ratio (the dilution ratio) of the diluted cleaning liquid to the cleaning liquid before dilution is preferably 10 to 10,000, more preferably 20 to 3,000, and still more preferably 50 to 1,000 in terms of mass ratio or volume ratio (volume ratio at 23° C.).

In addition, the cleaning liquid is preferably diluted with water from the viewpoint that it has more excellent defect inhibition performance.

That is, it is also possible suitably put into practical use a cleaning liquid (a diluted cleaning liquid) containing each component with an amount obtained by dividing a suitable content of each component (excluding water) contained in the above-described cleaning liquid by a dilution ratio (for example, 100) in the above-described range.

In other words, the suitable content of each component (excluding water) with respect to the total mass of the diluted cleaning liquid is an amount obtained, for example, by dividing the amount described as a suitable content of each component with respect to the total mass of the cleaning liquid (the cleaning liquid before dilution) by a dilution ratio (for example, 100) in the above-described range.

The change in the pH before and after dilution (the difference between the pH of the cleaning liquid before dilution and the pH of the diluted cleaning liquid) is preferably 2.0 or less, more preferably 1.8 or less, and still more preferably 1.5 or less.

It is preferable that the pH of the cleaning liquid before the dilution and the pH of the diluted cleaning liquid are each the suitable aspects described above.

A specific method for the diluting step of diluting the cleaning liquid may be carried out according to the above-described liquid preparation step for the cleaning liquid. Regarding the stirring device and the stirring method as well, which are used in the diluting step, the known stirring device mentioned in the liquid preparation step for the cleaning liquid may be used.

It is preferable to subject the water that is used in the diluting step to a purification treatment in advance. In addition, it is preferable to subject a diluted cleaning liquid obtained in a diluting step to a purifcation treatment.

Examples of the purification treatment include the ion component reducing treatment using an ion exchange resin, an RO membrane, or the like, and the foreign matter removal using filtering, which are described as the purification treatment for the cleaning liquid described above, and it is preferable to carry out any one of these treatments.

[Use Application of Cleaning Liquid]

The cleaning liquid is preferably used in a cleaning step of cleaning a semiconductor substrate that has been subjected to a chemical mechanical polishing (CMP) treatment. In addition, the cleaning liquid can also be used for cleaning a semiconductor substrate in a process of manufacturing a semiconductor substrate.

As described above, for the cleaning of the semiconductor substrate, a diluted cleaning liquid obtained by diluting the cleaning liquid may be used.

[Object to be Cleaned]

Examples of the object to be cleaned by the cleaning liquid include a semiconductor substrate having a metal-containing substance.

It is noted that in a case where “on the semiconductor substrate” is described, it encompasses, for example, front and back surfaces, a side surface, and the inside of a groove of the semiconductor substrate. In addition, the metal-containing substance on the semiconductor substrate encompasses not only a case where the metal-containing substance is directly on the surface of the semiconductor substrate but also a case where the metal-containing substance is present on the semiconductor substrate through another layer.

The object to be cleaned is preferably a semiconductor substrate containing at least one selected from the group consisting of a Ru-containing substance and a RuO₂-containing substance. Examples of the semiconductor substrate include a semiconductor substrate having a Ru-containing substance, a semiconductor substrate having a RuO₂-containing substance, and a laminate of a Ru-containing substance and a RuO₂-containing layer formed on the surface layer of the Ru-containing substance.

Examples of the metal contained in the metal-containing substance include at least one metal M selected from the group consisting of ruthenium (Ru), copper (Cu), cobalt (Co), tungsten (W), titanium (Ti), tantalum (Ta), chromium (Cr), hafnium (Hf), osmium (Os), platinum (Pt), nickel (Ni), manganese (Mn), copper (Cu), zirconium (Zr), molybdenum (Mo), lanthanum (La), and iridium (Ir).

The metal-containing substance may be any substance containing a metal (a metal atom), and examples thereof include a single body of the metal M, an alloy including the metal M, an oxide of the metal M, a nitride of the metal M, and an oxynitride of the metal M.

The metal-containing substance may be a mixture containing two or more of these compounds.

It is noted that the oxide, the nitride, and the oxynitride may be respectively any of a composite oxide, a composite nitride, and a composite oxynitride, which contain a metal.

The content of the metal atom in the metal-containing substance is preferably 10% by mass or more, more preferably 30% by mass or more, and still more preferably 50% by mass or more with respect to the total mass of the metal-containing substance. The upper limit thereof is preferably 100% by mass or less since the metal-containing substance may be the metal itself.

The semiconductor substrate preferably has a metal M-containing substance containing the metal M, more preferably has a metal-containing substance containing at least one metal selected from the group consisting of Cu, W, Co, Ti, Ta, Ru, and Mo, still more preferably has a metal-containing substance containing at least one metal selected from the group consisting of W, Co, Cu, Ti, Ta, and Ru (a tungsten-containing substance, a cobalt-containing substance, a copper-containing substance, a titanium-containing substance, and a tantalum-containing substance), and particularly preferably has a metal-containing substance containing at least one metal selected from the group consisting of Co, Cu, and Ru.

Examples of the semiconductor substrate, which is an object to be cleaned by using the cleaning liquid, include a substrate having a metal wiring line film, a barrier metal, and an insulating film on a surface of a wafer constituting the semiconductor substrate.

Examples of the wafer constituting a semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), and antimony (Sb)) and a p-type silicon wafer in which a silicon wafer is doped with a trivalent atom (for example, boron (B) and gallium (Ga)). Examples of the silicon of the silicon wafer include amorphous silicon, single crystal silicon, polycrystalline silicon, and polysilicon.

Among them, it is preferably a wafer consisting of a silicon-based material, such as a silicon wafer, a silicon carbide wafer, or a resin-based wafer (a glass epoxy wafer) including silicon.

The semiconductor substrate may have an insulating film on the wafer.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film), where a low-dielectric-constant (Low-k) film is preferable.

The metal-containing substance is also preferably a metal film containing a metal.

The metal film included in the semiconductor substrate is preferably a metal film containing the metal M, more preferably a metal film containing at least one metal selected from the group consisting of Cu, W, Co, Ti, Ta, Ru, and Mo, still more preferably a metal film containing at least one metal selected from the group consisting of W, Co, Cu, Ti, Ta, and Ru, particularly preferably a metal film containing at least one metal selected from the group consisting of W, Co, Cu, and Ru, and most preferably a metal film containing the Ru metal.

Examples of the metal film containing at least one metal selected from the group consisting of W, Co, Cu, and Ru include a film containing tungsten as a main component (a W-containing film), a film containing cobalt as a main component (a Co-containing film), a film containing copper as a main component (a Cu-containing film), and a film containing ruthenium as a main component (a Ru-containing film).

The semiconductor substrate preferably has at least one of a metal film containing tungsten or a metal film containing cobalt.

Examples of the ruthenium-containing film include a metal film consisting of only metallic ruthenium (a ruthenium metal film) and a metal film made of an alloy consisting of metallic ruthenium and another metal (a ruthenium alloy metal film). The ruthenium-containing film is often used as a barrier metal.

Examples of the tungsten-containing film (the metal film containing tungsten as a main component) include a metal film consisting of only tungsten (a tungsten metal film) and a metal film made of an alloy consisting of tungsten and another metal (a tungsten alloy metal film).

Examples of the tungsten alloy metal film include a tungsten-titanium alloy metal film (a WTi alloy metal film), and a tungsten-cobalt alloy metal film (a WCo alloy metal film).

The tungsten-containing film is used, for example, as a barrier metal or a connection part between the via and the wiring line.

Examples of the cobalt-containing film (metal film containing cobalt as a main component) include a metal film consisting of only metal cobalt (cobalt metal film), and a metal film (cobalt alloy metal film) made of an alloy consisting of metal cobalt and another metal.

Examples of the cobalt alloy metal film include a metal film made of an alloy consisting of one or more metals selected from titanium (Ti), chromium (Cr), iron (Fe), nickel (Ni), molybdenum (Mo), palladium (Pd), tantalum (Ta), and tungsten (W), and cobalt. More specific examples of the cobalt alloy metal film include a cobalt-titanium alloy metal film (a CoTi alloy metal film), a cobalt-chromium alloy metal film (a CoCr alloy metal film), a cobalt-iron alloy metal film (a CoFe alloy metal film), a cobalt-nickel alloy metal film (a CoNi alloy metal film), a cobalt-molybdenum alloy metal film (a CoMo alloy metal film), a cobalt-palladium alloy metal film (a CoPd alloy metal film), a cobalt-tantalum alloy metal film (a CoTa alloy metal film), and a cobalt-tungsten alloy metal film (a CoW alloy metal film).

The cleaning liquid is useful for a substrate having a cobalt-containing film. Among the cobalt-containing films, the cobalt metal film is often used as a wiring line film, and the cobalt alloy metal film is often used as a barrier metal.

It is also preferable that the semiconductor substrate has a copper-containing film (a metal film containing copper as a main component).

Examples of the copper-containing film include a wiring line film consisting of only metal copper (copper wiring line film), and a wiring line film made of an alloy consisting of metal copper and another metal (a copper alloy wiring line film).

Examples of the copper alloy wiring line film include a wiring line film made of an alloy consisting of one or more metals selected from aluminum (Al), titanium (Ti), chromium (Cr), manganese (Mn), tantalum (Ta), and tungsten (W), and copper. More specific examples of the copper alloy wiring line film include a copper-aluminum alloy wiring line film (a CuAl alloy wiring line film), a copper-titanium alloy wiring line film (a CuTi alloy wiring line film), a copper-chromium alloy wiring line film (a CuCr alloy wiring line film), a copper-manganese alloy wiring line film (a CuMn alloy wiring line film), a copper-tantalum alloy wiring line film (a CuTa alloy wiring line film), and a copper-tungsten alloy wiring line film (a CuW alloy wiring line film).

Further, the cleaning liquid may be preferably used for cleaning a substrate which has, on a wafer constituting a semiconductor substrate, at least a copper-containing wiring line film and a metal film (a cobalt barrier metal) that is composed of only metallic cobalt and is a barrier metal of the copper-containing wiring line film, where the copper-containing wiring line film is in contact with the cobalt barrier metal on the surface of the substrate.

Methods for forming the insulating film, the ruthenium-containing film, the tungsten-containing film, the copper-containing film, and the cobalt-containing film on a wafer constituting the semiconductor substrate are not particularly limited as long as they are methods that are generally carried out in this field.

Examples of a method of forming an insulating film include a method in which a wafer constituting a semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming a ruthenium-containing film, a tungsten-containing film, a copper-containing film, and a cobalt-containing film include a method of forming a circuit on a wafer having the above-described insulating film by a known method using a means such as a resist, and then forming a ruthenium-containing film, a tungsten-containing film, a copper-containing film, and a cobalt-containing film according to a method such as plating or a CVD method.

<CMP Treatment>

The CMP treatment is a treatment in which a surface of a substrate having a metal wiring line film, a barrier metal, and an insulating film is flattened by a combined action of a chemical action using a polishing slurry including polishing fine particles (abrasive grains) and mechanical polishing.

A surface of the semiconductor substrate that has been subjected to the CMP treatment may have impurities remaining thereon, such as abrasive grains (for example, silica and alumina) used in the CMP treatment, a polished metal wiring line film, and metal impurities (metal residue) derived from the barrier metal. In addition, an organic residue derived from a CMP treatment liquid used in the CMP treatment may remain. For example, since these impurities may short-circuit the wiring lines and deteriorate the electrical characteristics of the semiconductor substrate, the semiconductor substrate that has been subjected to the CMP treatment is subjected to a cleaning treatment for removing these impurities from the surface.

Examples of the semiconductor substrate that has been subjected to the CMP treatment include the substrate that has been subjected to a CMP treatment, described in Vol. 84, No. 3, 2018; however, examples thereof are not limited thereto.

<Buffing Treatment>

A surface of the semiconductor substrate, which is an object to be cleaned by using the cleaning liquid, may be subjected to a CMP treatment and then to a buffing treatment.

The buffing treatment is a treatment of reducing impurities on the surface of the semiconductor substrate using a polishing pad. Specifically, the surface of the semiconductor substrate that has been subjected to the CMP treatment is brought into contact with the polishing pad, and the semiconductor substrate and the polishing pad are relatively slid while supplying a composition for a buffing treatment to the contact portion. As a result, impurities on the surface of the semiconductor substrate are removed by a frictional force of the polishing pad and a chemical action of a composition for a buffing treatment.

As the composition for a buffing treatment, a known composition for a buffing treatment can be appropriately used depending on the kind of the semiconductor substrate, and the kind and the amount of the impurities to be removed. Examples of the component included in the composition for a buffing treatment include a water-soluble polymer such as polyvinyl alcohol, water as a dispersion medium, and an acid such as nitric acid.

In addition, in one embodiment of the buffing treatment, it is preferable that a semiconductor substrate is buffed using the cleaning liquid as the composition for a buffing treatment.

A polishing device, polishing conditions, and the like, which are used in the buffing treatment, can be appropriately selected from known devices and conditions according to the kind of the semiconductor substrate, the object to be removed, and the like. Examples of the buffing treatment include the treatments described in paragraphs [0085] to [0088] of WO2017/169539A, the contents of which are incorporated in the present specification.

[Cleaning Method for Semiconductor Substrate]A cleaning method for a semiconductor substrate is not particularly limited as long as it includes a cleaning step of cleaning a semiconductor substrate that has been subjected to a CMP treatment, using the cleaning liquid. The cleaning method for a semiconductor substrate preferably includes a step of applying a diluted cleaning liquid obtained in a diluting step to the semiconductor substrate that has been subjected to a CMP treatment to carry out cleaning.

The cleaning step of cleaning the semiconductor substrate using the cleaning liquid may appropriately employ a mode that is generally carried out in this field, such as scrub cleaning in which a cleaning member such as a brush is physically brought into contact with a surface of the semiconductor substrate while supplying a cleaning liquid to a semiconductor substrate, thereby removing residues; an immersion method in which a semiconductor substrate is immersed in a cleaning liquid; a spinning (dropping) method in which a cleaning liquid is dropped while rotating a semiconductor substrate; or a spray method in which a cleaning liquid is sprayed, as long as it is a known method that is carried out on a semiconductor substrate that has been subjected to a CMP treatment. In the immersion type cleaning, it is preferable to subject the cleaning liquid in which the semiconductor substrate is immersed to an ultrasonic treatment from the viewpoint that impurities remaining on the surface of the semiconductor substrate can be further reduced.

The cleaning step may be carried out only once or twice or more. In a case of carrying out cleaning two or more times, the same method may be repeated or different methods may be combined.

The cleaning method for a semiconductor substrate may be any one of a single-wafer method or a batch method.

The single-wafer method is generally a method of treating semiconductor substrates one by one, and the batch method is generally a method of treating a plurality of semiconductor substrates at the same time.

The temperature of the cleaning liquid that is used for cleaning a semiconductor substrate is not particularly limited as long as it is a temperature that is usually used in this field. Generally, the cleaning is carried out at room temperature (about 25° C.), but any temperature can be selected in order to improve the cleaning properties and suppress the damage resistance to a member. For example, the temperature of the cleaning liquid is preferably 10° C. to 60° C., and more preferably 15° C. to 50° C.

The pH of the cleaning liquid is preferably the suitable aspect of the pH of the cleaning liquid described above. The pH of the diluted cleaning liquid is also preferably the suitable aspect of the pH of the cleaning liquid described above.

The cleaning time in the cleaning of the semiconductor substrate can be appropriately changed depending on the kind, content, and the like of the component contained in the cleaning liquid. Practically, it is preferably 10 seconds to 2 minutes, more preferably 20 seconds to 1 minute 30 seconds, and still more preferably 30 seconds to 1 minute.

The supply amount (the supply rate) of the cleaning liquid in the cleaning step for the semiconductor substrate is preferably 50 to 5,000 mL/min and more preferably 500 to 2,000 mL/min.

In the cleaning of the semiconductor substrate, a mechanical stirring method may be used in order to further improve the cleaning ability of the cleaning liquid.

Examples of the mechanical stirring method include a method of circulating a cleaning liquid on a semiconductor substrate, a method of flowing or spraying a cleaning liquid on a semiconductor substrate, and a method of stirring a cleaning liquid with an ultrasonic or a megasonic.

After cleaning the semiconductor substrate, a step of rinsing and cleaning the semiconductor substrate with a solvent (hereinafter, also referred to as a “rinsing step”) may be carried out.

The rinsing step is preferably a step which is carried out continuously subsequently after the cleaning step for the semiconductor substrate and in which rinsing is carried out with a rinsing solvent (a rinsing liquid) over 5 seconds to 5 minutes. The rinsing step may be carried out using the above-described mechanical stirring method.

Examples of the rinsing solvent include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (an aqueous ammonium hydroxide that has been diluted, or the like) may be used.

As a method of bringing the rinsing solvent into contact with the semiconductor substrate, the above-described method of bringing the cleaning liquid into contact with the semiconductor substrate can be similarly applied.

In addition, after the rinsing step, a drying step of drying the semiconductor substrate may be carried out.

Examples of the drying method include a spin drying method, a method of flowing a dry gas onto a semiconductor substrate, a method of heating a substrate by a heating means such as a hot plate and an infrared lamp, a Marangoni drying method, a Rotagoni drying method, an isopropyl alcohol (IPA) drying method, and a method of any combinations of these methods.

### Examples

Hereinbelow, the present invention will be described in more detail with reference to Examples. The materials, the amounts of the materials to be used, the proportions, and the like shown in the Examples below may be modified as appropriate as long as the modifications do not depart from the spirit of the present invention. Accordingly, the scope of the present invention should not be construed as being limited to Examples shown below.

In the following Examples, the pH of the cleaning liquid was measured at 25° C. using a pH meter (manufactured by HORIBA, Ltd., model “F-74”) in accordance with JIS Z8802-1984.

In addition, in the production of cleaning liquids of Examples and Comparative Examples, handling of the container, and preparation, filling, storage, and analytical measurement of the cleaning liquids were all carried out in a clean room satisfying a level of ISO Class 2 or lower.

[Raw Material for Cleaning Liquid]

The following compounds were used to produce a cleaning liquid. It is noted that as various components used in Examples, those all classified into a semiconductor grade or a high-purity grade equivalent thereto were used.

[Purine Compound]
Xanthine
Adenosine
Adenine
Guanine
Hypoxanthine
Uric acid
Purine
Caffeine
Isoguanine
Theobromine
Theophylline

[Compound A]
MDEA: N-methyldiethanolamine
T-BDEA: N-tert-butyldiethanolamine
Bis-HEAP: 1-[bis(2-hydroxyethyl)amino]-2-propanol
Ph-DEA: N-phenyldiethanolamine
EDEA: N-ethyldiethanolamine
BDEA: N-butyldiethanolamine
N-MEA: N-methylethanolamine
DMAE: 2-(dimethylamino)ethanol
DMAMP: 2-(dimethylamino)-2-methyl-1-propanol
MAMP: (2-methyl-2-(methylamino)propane-1-ol

[Quaternary Ammonium Compound]
Tris: Tris(2-hydroxyethyl)methylammonium hydroxide
Choline: 2-hydroxyethyltrimethylammonium hydroxide
ETMAH: ethyltrimethylammonium hydroxide

[Organic Acid]
Tartaric acid
Citric acid
Malonic acid
Succinic acid
EDTPO: ethylenediaminetetra(methylenephosphonic acid)
HEDPO: 1-hydroxyethylidene-1,1′-diphosphonic acid

[Other Additives]
MEA: monoethanolamine
Polyacrylic acid (Mw=700,000): manufactured by Toagosei Co., Ltd., trade name: “JURYMER AC-10H”
Polyacrylic acid (Mw=55,000): manufactured by Toagosei Co., Ltd., trade name: “JURYMER AC-10L”
Polyacrylic acid (Mw=6,000): manufactured by Toagosei Co., Ltd., trade name: “ARON A-10SL”
Polymaleic acid (Mw=2,000): manufactured by NOF Corporation, trade name: “NONPOL PWA-50W”
Styrene-maleic acid copolymer: manufactured by DKS Co., Ltd., trade name: “DKS DISCOAT N-10”
Styrene-maleic acid half ester copolymer: manufactured by DKS Co., Ltd., trade name: “DKS DISCOAT N-14”
Naphthalene sulfonate formalin condensate Na salt: manufactured by DKS Co., Ltd., trade name: “LAVELIN FD-40”
1,2,4-triazole
1,2,3-triazole
Nonionic X: Compound shown below

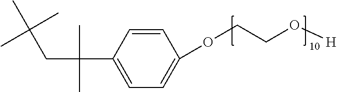

Cysteine
Thioglycerol
3-mercapto-1,2,4-triazole
Polyethylene glycol
Iodic acid
Periodic acid
Morpholine (pKa: 8.006)
Tetramethylguanidine: 1,1,3,3-tetramethylguanidine (pKa: 13.6)
DABCO: 1,4-diazabicyclo[2.2.2]octane (pKa: 8.7)
DBU: diazabicycloundecene (pKa: 13.28)
DBN: diazabicyclononene (pKa: 13.42)
PMDTA: N,N,N′,N″,N″-pentamethyldiethylenetriamine
2-(2-aminoethylamino)ethanol
Hydrazine
AMP: 2-amino-2-methyl-1-propanol
MED: tetramethylethylenediamine

[pH Adjusting Agent and Ultrapure Water]

In addition, the step of producing the cleaning liquids in present Examples and Comparative Examples, any one of potassium hydroxide (KOH) or sulfuric acid (H₂SO₄) as well as commercially available ultrapure water (manufactured by FUJIFILM Wako Pure Chemical Corporation) was used as the pH adjusting agent to adjust the pH as shown in the table.

It is noted that the content of the pH adjusting agent (potassium hydroxide or sulfuric acid) was 2% by mass or less with respect to the total mass of the cleaning liquid in any one of the cleaning liquids of Examples or Comparative Examples.

In the cleaning liquid, the remaining component (the remainder) that is neither a component specified as a component of the cleaning liquid in the table nor the pH adjusting agent is ultrapure water.

[Production of Cleaning Liquid]

Next, a method for producing the cleaning liquid will be described by taking Example 1 as an example.

Respective amounts of xanthine, MEDA, Tris, and tartaric acid were added to ultrapure water so that the cleaning liquid to be finally obtained had the formulation shown in the table below, and then a pH adjusting agent was added thereto so that the pH of the cleaning liquid to be prepared was 12.5. The obtained mixed solution was sufficiently stirred to obtain a cleaning liquid of Example 1.

According to the production method of Example 1, a cleaning liquid of each Example or each Comparative Example, having the composition shown in the table below, was individually produced.

[Evaluation of Cleaning Performance (Organic Residue)]

The cleaning liquid produced by the above-described method was used to evaluate the cleaning performance (the organic residue) in a case where a metal film was subjected to chemical mechanical polishing.

In the test of each Example and each Comparative Example, 1 mL of the cleaning liquid of each Example and each Comparative Example was aliquoted and diluted 100-fold by volume with ultrapure water to prepare a sample of the diluted cleaning liquid.

Using FREX300S-II (a polishing device, manufactured by Ebara Corporation) and using BSL8872 (trade name, manufactured by FUJIFILM Electronic Materials Co., Ltd.) as a polishing liquid, a wafer (diameter: 12 inches) having a BD1 film (a Low-K film) on the surface was polished under the conditions of a polishing pressure of 2.0 psi and a polishing liquid supply rate of 0.28 mL/(min cm²), and a polishing time of 60 seconds.

Then, scrub cleaning was carried out for 60 minutes using the sample of each diluted cleaning liquid adjusted to room temperature (23° C.), and a drying treatment was carried out. A defect detection device (ComPlus-II, manufactured by Applied Materials, Inc.) was used to measure the number of detections of signal intensities corresponding to defects having a length of more than 0.1 μm on the obtained polished surface of the wafer, each of the defects was measured with a scanning electron microscope (SEM), and the measurement target was specified by the energy dispersion type X-ray analysis (EDX) of the constitutional elements as necessary.

From this, the number of defects based on the organic residue (the residue containing an organic substance as a main component) on the polished surface of the wafer was determined.
A: The number of target defects is 20 or less.
B: The number of target defects is more than 20 and 30 or less.
C: The number of target defects is more than 30 and 40 or less.
D: The number of target defects is more than 40 and 50 or less.
E: The number of target defects is more than 50.

It is noted that the pH of each of the cleaning liquids of Examples 1 to 40 and 45 to 90 in a state of being a diluted cleaning liquid after being diluted 100-fold by volume was 11.0.

In addition, in a state where each of the cleaning liquids of Examples 41 to 44 was a diluted cleaning liquid after being diluted 100-fold by volume, the pH of the cleaning liquid of Example 41 was 8.2, the pH of the cleaning liquid of Example 42 was 9.8, the pH of the cleaning liquid of Example 43 was 10.5, and the pH of the cleaning liquid of Example 44 was 11.4.

The pH of each of the cleaning liquids of Examples 95 to 104, 113, 114, 116, and 117 in a state of being a diluted cleaning liquid after being diluted 100-fold by volume was 11.0.

In addition, the pH of each of the cleaning liquids of Examples 105 to 112, 115, and 118 in a state of being a diluted cleaning liquid after being diluted 100-fold by volume was 10.8.

[Evaluation of Ruthenium Oxide Dissolving Ability]

A 2×2 cm ruthenium oxide coupon wafer was prepared.

The wafer was placed in a container filled with the cleaning liquid of each Example or each Comparative Example and subjected to an immersion treatment at room temperature (25° C.) for 30 minutes. Then, the film thickness of the obtained wafer was measured, and the etching rate (Å/min) was determined from the film thickness difference before and after the immersion treatment and evaluated according to the following evaluation standards.
A: 5 Å/min or more
B: 3 Å/min or more and less than 5 Å/min
C: 2 Å/min or more and less than 3 Å/min
D: 1 Å/min or more and less than 2 Å/min
E: Less than 1 Å/min

[Results]

In the table, the column of “Content (% by mass” indicates the content (% by mass) of each component with respect to the total mass of the cleaning liquid.

The column of “Concentration of solid contents (% by mass)” indicates the content (% by mass) of respective components with respect to the total mass of the components in the cleaning liquid excluding the solvent.

The column of “(B)/(A)” indicates the mass ratio of the content (B) of the purine compound to the content (A) of the compound A (content (B) of purine compound/content (A) of compound A).

The numerical value in the column of “pH before dilution” indicates the pH of the above-described cleaning liquid at 25° C., measured with the pH meter, where the cleaning liquid is undiluted (before 100-fold dilution). That is, the pH of the undiluted cleaning liquid is shown.

TABLE 1

| | Cleaning liquid for semiconductor substrate | | | | | | | | |
|---|---|---|---|---|---|---|---|---|---|
| | | | | | | | Tertiary ammonium | | |
| | Purine compound (B) | | | Compound (A) | | | compound | | |
| | | | Concen- | | | Concen- | | | Concen- |
| | | | tration of | | | tration of | | | tration of |
| | | Con- | solid | | Con- | solid | | Con- | solid |
| | | tent | content | | tent | content | | tent | content |
| | | (% by | (% by | | (% by | (% by | | (% by | (% by |
| | Kind | mass) | mass) | Kind | mass) | mass) | Kind | mass) | mass) |
| Compar- | — | — | — | MDEA | 1.0 | 16.4 | Tris | 5.0 | 82.0 |
| ative | | | | | | | | | |
| Example | | | | | | | | | |
| 1 | | | | | | | | | |
| Compar- | Xanthine | 0.2 | 3.8 | — | — | — | Tris | 5.0 | 94.3 |
| ative | | | | | | | | | |
| Example | | | | | | | | | |
| 2 | | | | | | | | | |
| Compar- | Adenosine | 0.2 | 3.2 | — | — | — | Tris | 5.0 | 79.4 |
| ative | | | | | | | | | |
| Example | | | | | | | | | |
| 3 | | | | | | | | | |
| Example | Xanthine | 0.2 | 3.2 | MDEA | 1.0 | 15.9 | Tris | 5.0 | 79.4 |
| 1 | | | | | | | | | |
| Example | Adenine | 0.2 | 3.2 | MDEA | 1.0 | 15.9 | Tris | 5.0 | 79.4 |
| 2 | | | | | | | | | |
| Example | Guanine | 0.2 | 3.2 | MDEA | 1.0 | 15.9 | Tris | 5.0 | 79.4 |
| 3 | | | | | | | | | |
| Example | Hypoxanthine | 0.2 | 3.2 | MDEA | 1.0 | 15.9 | Tris | 5.0 | 79.4 |
| 4 | | | | | | | | | |
| Example | Uric acid | 0.2 | 3.2 | MDEA | 1.0 | 15.9 | Tris | 5.0 | 79.4 |
| 5 | | | | | | | | | |
| Example | Purine | 0.2 | 3.2 | MDEA | 1.0 | 15.9 | Tris | 5.0 | 79.4 |
| 6 | | | | | | | | | |
| Example | Caffeine | 0.2 | 3.2 | MDEA | 1.0 | 15.9 | Tris | 5.0 | 79.4 |
| 7 | | | | | | | | | |
| Example | Isoguanine | 0.2 | 3.2 | MDEA | 1.0 | 15.9 | Tris | 5.0 | 79.4 |
| 8 | | | | | | | | | |
| Example | Theobromine | 0.2 | 3.2 | MDEA | 1.0 | 15.9 | Tris | 5.0 | 79.4 |
| 9 | | | | | | | | | |
| Example | Theophylline | 0.2 | 3.2 | MDEA | 1.0 | 15.9 | Tris | 5.0 | 79.4 |
| 10 | | | | | | | | | |
| Example | Xanthine | 0.05 | 0.8 | MDEA | 1.0 | 16.3 | Tris | 5.0 | 81.3 |
| 11 | | | | | | | | | |
| Example | Xanthine | 0.1 | 1.6 | MDEA | 1.0 | 16.1 | Tris | 5.0 | 80.6 |
| 12 | | | | | | | | | |
| Example | Xanthine | 0.5 | 7.6 | MDEA | 1.0 | 15.2 | Tris | 5.0 | 75.8 |
| 13 | | | | | | | | | |
| Example | Xanthine | 1.0 | 14.1 | MDEA | 1.0 | 14.1 | Tris | 5.0 | 70.4 |
| 14 | | | | | | | | | |
| Example | Xanthine | 3.5 | 36.5 | MDEA | 1.0 | 10.4 | Tris | 5.0 | 52.1 |
| 15 | | | | | | | | | |
| Example | Uric acid | 1.0 | 14.1 | MDEA | 1.0 | 14.1 | Tris | 5.0 | 70.4 |
| 16 | | | | | | | | | |
| Example | Uric acid | 3.5 | 36.5 | MDEA | 1.0 | 10.4 | Tris | 5.0 | 52.1 |
| 17 | | | | | | | | | |
| Example | Theophylline | 1.0 | 14.1 | MDEA | 1.0 | 14.1 | Tris | 5.0 | 70.4 |
| 18 | | | | | | | | | |
| Example | Theophylline | 3.5 | 36.5 | MDEA | 1.0 | 10.4 | Tris | 5.0 | 52.1 |
| 19 | | | | | | | | | |
| Example | Caffeine | 1.0 | 14.1 | MDEA | 1.0 | 14.1 | Tris | 5.0 | 70.4 |
| 20 | | | | | | | | | |
| Example | Caffeine | 3.5 | 36.5 | MDEA | 1.0 | 10.4 | Tris | 5.0 | 52.1 |
| 21 | | | | | | | | | |
| Example | Xanthine | 0.2 | 3.2 | t-BDEA | 1.0 | 15.9 | Tris | 5.0 | 79.4 |
| 22 | | | | | | | | | |
| Example | Xanthine | 0.2 | 3.2 | Bis-HEAP | 1.0 | 15.9 | Tris | 5.0 | 79.4 |
| 23 | | | | | | | | | |
| Example | Xanthine | 0.2 | 3.2 | Ph-DEA | 1.0 | 15.9 | Tris | 5.0 | 79.4 |
| 24 | | | | | | | | | |
| Example | Xanthine | 0.2 | 3.2 | EDEA | 1.0 | 15.9 | Tris | 5.0 | 79.4 |
| 25 | | | | | | | | | |

| | Cleaning liquid for semiconductor substrate | | | | | | | | | |
|---|---|---|---|---|---|---|---|---|---|---|
| | Organic acid | | | Other additives | | | | | | |
| | | | Concen- | | | Concen- | | | | Ruthe- |
| | | | tration of | | | tration of | | | Cleaning | nium |
| | | Con- | solid | | Con- | solid | | pH | perfor- | oxide |
| | | tent | content | | tent | content | | before | mance | dis- |
| | | (% by | (% by | | (% by | (% by | (B)/ | dilu- | (organic | solving |
| | Kind | mass) | mass) | Kind | mass) | mass) | (A) | tion | residue) | ability |
| Compar- | Tartaric | 0.1 | 1.6 | — | — | — | — | 12.5 | D | D |
| ative | acid | | | | | | | | | |
| Example | | | | | | | | | | |
| 1 | | | | | | | | | | |
| Compar- | Tartaric | 0.1 | 1.9 | — | — | — | — | 12.5 | E | E |
| ative | acid | | | | | | | | | |
| Example | | | | | | | | | | |
| 2 | | | | | | | | | | |
| Compar- | Tartaric | 0.1 | 1.6 | — | — | — | — | 12.5 | D | D |
| ative | acid | | | | | | | | | |
| Example | | | | | | | | | | |
| 3 | | | | | | | | | | |
| Example | Tartaric | 0.1 | 1.6 | MEA | 1.0 | 15.9 | 0.2 | 12.5 | A | A |
| 1 | acid | | | | | | | | | |
| Example | Tartaric | 0.1 | 1.6 | — | — | — | 0.2 | 12.5 | C | A |
| 2 | acid | | | | | | | | | |
| Example | Tartaric | 0.1 | 1.6 | — | — | — | 0.2 | 12.5 | C | A |
| 3 | acid | | | | | | | | | |
| Example | Tartaric | 0.1 | 1.6 | — | — | — | 0.2 | 12.5 | A | A |
| 4 | acid | | | | | | | | | |
| Example | Tartaric | 0.1 | 1.6 | — | — | — | 0.2 | 12.5 | B | A |
| 5 | acid | | | | | | | | | |
| Example | Tartaric | 0.1 | 1.6 | — | — | — | 0.2 | 12.5 | B | A |
| 6 | acid | | | | | | | | | |
| Example | Tartaric | 0.1 | 1.6 | — | — | — | 0.2 | 12.5 | B | A |
| 7 | acid | | | | | | | | | |
| Example | Tartaric | 0.1 | 1.6 | — | — | — | 0.2 | 12.5 | C | A |
| 8 | acid | | | | | | | | | |
| Example | Tartaric | 0.1 | 1.6 | — | — | — | 0.2 | 12.5 | C | A |
| 9 | acid | | | | | | | | | |
| Example | Tartaric | 0.1 | 1.6 | — | — | — | 0.2 | 12.5 | B | A |
| 10 | acid | | | | | | | | | |
| Example | Tartaric | 0.1 | 1.6 | — | — | — | 0.05 | 12.5 | A | A |
| 11 | acid | | | | | | | | | |
| Example | Tartaric | 0.1 | 1.6 | — | — | — | 0.1 | 12.5 | A | A |
| 12 | acid | | | | | | | | | |
| Example | Tartaric | 0.1 | 1.5 | — | — | — | 0.5 | 12.5 | A | A |
| 13 | acid | | | | | | | | | |
| Example | Tartaric | 0.1 | 1.4 | — | — | — | 1.0 | 12.5 | A | A |
| 14 | acid | | | | | | | | | |
| Example | Tartaric | 0.1 | 1.0 | — | — | — | 3.5 | 12.5 | B | A |
| 15 | acid | | | | | | | | | |
| Example | Tartaric | 0.1 | 1.4 | — | — | — | 1.0 | 12.5 | B | A |
| 16 | acid | | | | | | | | | |
| Example | Tartaric | 0.1 | 1.0 | — | — | — | 3.5 | 12.5 | C | A |
| 17 | acid | | | | | | | | | |
| Example | Tartaric | 0.1 | 1.4 | — | — | — | 1.0 | 12.5 | B | A |
| 18 | acid | | | | | | | | | |
| Example | Tartaric | 0.1 | 1.0 | — | — | — | 3.5 | 12.5 | C | A |
| 19 | acid | | | | | | | | | |
| Example | Tartaric | 0.1 | 1.4 | — | — | — | 1.0 | 12.5 | B | A |
| 20 | acid | | | | | | | | | |
| Example | Tartaric | 0.1 | 1.0 | — | — | — | 3.5 | 12.5 | C | A |
| 21 | acid | | | | | | | | | |
| Example | Tartaric | 0.1 | 1.6 | — | — | — | 0.2 | 12.5 | A | B |
| 22 | acid | | | | | | | | | |
| Example | Tartaric | 0.1 | 1.6 | — | — | — | 0.2 | 12.5 | A | C |
| 23 | acid | | | | | | | | | |
| Example | Tartaric | 0.1 | 1.6 | — | — | — | 0.2 | 12.5 | A | B |
| 24 | acid | | | | | | | | | |
| Example | Tartaric | 0.1 | 1.6 | — | — | — | 0.2 | 12.5 | A | B |
| 25 | acid | | | | | | | | | |

TABLE 2

| | Cleaning liquid for semiconductor substrate | | | | | | | | |
|---|---|---|---|---|---|---|---|---|---|
| | | | | | | | Tertiary ammonium | | |
| | Purine compound (B) | | | Compound (A) | | | compound | | |
| | | | Concen- | | | Concen- | | | Concen- |
| | | | tration of | | | tration of | | | tration of |
| | | Con- | solid | | Con- | solid | | Con- | solid |
| | | tent | content | | tent | content | | tent | content |
| | | (% by | (% by | | (% by | (% by | | (% by | (% by |
| | Kind | mass) | mass) | Kind | mass) | mass) | Kind | mass) | mass) |
| Example | Xanthine | 0.2 | 3.2 | BDEA | 1.0 | 15.9 | Tris | 5.0 | 79.4 |
| 26 | | | | | | | | | |
| Example | Xanthine | 0.2 | 3.2 | N-MEA | 1.0 | 15.9 | Tris | 5.0 | 79.4 |
| 27 | | | | | | | | | |
| Example | Xanthine | 0.2 | 3.2 | DMAE | 1.0 | 15.9 | Tris | 5.0 | 79.4 |
| 28 | | | | | | | | | |
| Example | Xanthine | 0.2 | 3.7 | MDEA | 0.1 | 1.9 | Tris | 5.0 | 92.6 |
| 29 | | | | | | | | | |
| Example | Xanthine | 0.2 | 3.4 | MDEA | 0.5 | 8.6 | Tris | 5.0 | 86.2 |
| 30 | | | | | | | | | |
| Example | Xanthine | 0.2 | 2.7 | MDEA | 2.0 | 27.4 | Tris | 5.0 | 68.5 |
| 31 | | | | | | | | | |
| Example | Xanthine | 0.2 | 2.4 | MDEA | 3.0 | 36.1 | Tris | 5.0 | 60.2 |
| 32 | | | | | | | | | |
| Example | Xanthine | 0.2 | 1.9 | MDEA | 5.0 | 48.5 | Tris | 5.0 | 48.5 |
| 33 | | | | | | | | | |
| Example | Xanthine | 0.2 | 3.2 | MDEA | 1.0 | 15.9 | Tris | 5.0 | 79.4 |
| 34 | | | | | | | | | |
| Example | Xanthine | 0.2 | 3.2 | MDEA | 1.0 | 15.9 | Tris | 5.0 | 79.4 |
| 35 | | | | | | | | | |
| Example | Xanthine | 0.2 | 2.7 | MDEA | 2.0 | 27.4 | Tris | 5.0 | 68.5 |
| 36 | | | | | | | | | |
| Example | Xanthine | 0.2 | 1.8 | MDEA | 1.0 | 8.9 | Tris | 5.0 | 44.6 |
| 37 | | | | | | | | | |
| Example | Xanthine | 0.2 | 2.8 | MDEA | 1.0 | 13.9 | Tris | 5.0 | 69.4 |
| 38 | | | | | | | | | |
| Example | Xanthine | 0.2 | 3.0 | MDEA | 1.0 | 14.9 | Tris | 5.0 | 74.6 |
| 39 | | | | | | | | | |
| Example | Xanthine | 0.2 | 3.2 | MDEA | 1.0 | 16.0 | Tris | 5.0 | 80.0 |
| 40 | | | | | | | | | |
| Example | Xanthine | 0.2 | 3.2 | MDEA | 1.0 | 15.9 | Tris | 5.0 | 79.4 |
| 41 | | | | | | | | | |
| Example | Xanthine | 0.2 | 3.2 | MDEA | 1.0 | 15.9 | Tris | 5.0 | 79.4 |
| 42 | | | | | | | | | |
| Example | Xanthine | 0.2 | 3.2 | MDEA | 1.0 | 15.9 | Tris | 5.0 | 79.4 |
| 43 | | | | | | | | | |
| Example | Xanthine | 0.2 | 3.2 | MDEA | 1.0 | 15.9 | Tris | 5.0 | 79.4 |
| 44 | | | | | | | | | |
| Example | Xanthine | 0.2 | 3.2 | MDEA | 1.0 | 15.9 | Choline | 5.0 | 79.4 |
| 45 | | | | | | | | | |
| Example | Xanthine | 0.2 | 3.2 | MDEA | 1.0 | 15.9 | ETMAH | 5.0 | 79.4 |
| 46 | | | | | | | | | |
| Example | Xanthine | 2.1 | 28.8 | MDEA | 0.1 | 1.4 | Tris | 5.0 | 68.5 |
| 47 | | | | | | | | | |
| Example | Xanthine | 0.03 | 0.2 | MDEA | 10.0 | 66.1 | Tris | 5.0 | 33.0 |
| 48 | | | | | | | | | |
| Example | Xanthine | 0.2 | 1.8 | MDEA | 1.0 | 8.8 | Tris | 10.0 | 88.5 |
| 49 | | | | | | | | | |
| Example | Xanthine | 0.2 | 2.3 | MDEA | 1.0 | 11.4 | Tris | 7.5 | 85.2 |
| 50 | | | | | | | | | |
| Example | Xanthine | 0.2 | 5.3 | MDEA | 1.0 | 26.3 | Tris | 2.5 | 65.8 |
| 51 | | | | | | | | | |
| Example | Xanthine | 0.2 | 8.7 | MDEA | 1.0 | 43.5 | Tris | 1.0 | 43.5 |
| 52 | | | | | | | | | |

| | Cleaning liquid for semiconductor substrate | | | | | | |
|---|---|---|---|---|---|---|---|
| | Organic acid | | | | | | |
| | | | Concen- | | | | |
| | | | tration of | | | | |
| | | Con- | solid | | | Cleaning | Ruthenium |
| | | tent | content | | pH | performance | oxide |
| | | (% by | (% by | | before | (organic | dissolving |
| | Kind | mass) | mass) | (B)/(A) | dilution | residue) | ability |
| Example | Tartaric | 0.1 | 1.6 | 0.2 | 12.5 | A | C |
| 26 | acid | | | | | | |
| Example | Tartaric | 0.1 | 1.6 | 0.2 | 12.5 | A | B |
| 27 | acid | | | | | | |
| Example | Tartaric | 0.1 | 1.6 | 0.2 | 12.5 | A | C |
| 28 | acid | | | | | | |
| Example | Tartaric | 0.1 | 1.9 | 2.0 | 12.5 | A | C |
| 29 | acid | | | | | | |
| Example | Tartaric | 0.1 | 1.7 | 0.4 | 12.5 | A | A |
| 30 | acid | | | | | | |
| Example | Tartaric | 0.1 | 1.4 | 0.1 | 12.5 | A | A |
| 31 | acid | | | | | | |
| Example | Tartaric | 0.1 | 1.2 | 0.07 | 12.5 | A | A |
| 32 | acid | | | | | | |
| Example | Tartaric | 0.1 | 1.0 | 0.04 | 12.5 | B | B |
| 33 | acid | | | | | | |
| Example | Citric | 0.1 | 1.6 | 0.2 | 12.5 | A | A |
| 34 | acid | | | | | | |
| Example | Malonic | 0.1 | 1.6 | 0.2 | 12.5 | A | A |
| 35 | acid | | | | | | |
| Example | Succinic | 0.1 | 1.4 | 0.1 | 12.5 | A | A |
| 36 | acid | | | | | | |
| Example | Tartaric | 5.0 | 44.6 | 0.2 | 12.5 | A | A |
| 37 | acid | | | | | | |
| Example | Tartaric | 1.0 | 13.9 | 0.2 | 12.5 | A | A |
| 38 | acid | | | | | | |
| Example | Tartaric | 0.5 | 7.5 | 0.2 | 12.5 | A | A |
| 39 | acid | | | | | | |
| Example | Tartaric | 0.05 | 0.8 | 0.2 | 12.5 | A | A |
| 40 | acid | | | | | | |
| Example | Tartaric | 0.1 | 1.6 | 0.2 | 9.0 | B | B |
| 41 | acid | | | | | | |
| Example | Tartaric | 0.1 | 1.6 | 0.2 | 11.0 | A | A |
| 42 | acid | | | | | | |
| Example | Tartaric | 0.1 | 1.6 | 0.2 | 12.0 | A | A |
| 43 | acid | | | | | | |
| Example | Tartaric | 0.1 | 1.6 | 0.2 | 13.0 | A | A |
| 44 | acid | | | | | | |
| Example | Tartaric | 0.1 | 1.6 | 0.2 | 12.5 | A | A |
| 45 | acid | | | | | | |
| Example | Tartaric | 0.1 | 1.6 | 0.2 | 12.5 | A | A |
| 46 | acid | | | | | | |
| Example | Tartaric | 0.1 | 1.4 | 20.6 | 12.5 | C | C |
| 47 | acid | | | | | | |
| Example | Tartaric | 0.1 | 0.7 | 0.003 | 12.5 | C | C |
| 48 | acid | | | | | | |
| Example | Tartaric | 0.1 | 0.9 | 0.2 | 12.5 | A | A |
| 49 | acid | | | | | | |
| Example | Tartaric | 0.1 | 1.1 | 0.2 | 12.5 | A | A |
| 50 | acid | | | | | | |
| Example | Tartaric | 0.1 | 2.6 | 0.2 | 12.5 | A | A |
| 51 | acid | | | | | | |
| Example | Tartaric | 0.1 | 4.3 | 0.2 | 12.5 | A | B |
| 52 | acid | | | | | | |

TABLE 3

| | Cleaning liquid for semiconductor substrate | | | | | | | | |
|---|---|---|---|---|---|---|---|---|---|
| | Purine compound (B) | | | Compound (A) | | | Tertiary ammonium compound | | |
| | | | Concen- | | | Concen- | | | Concen- |
| | | | tration of | | | tration of | | | tration of |
| | | Con- | solid | | Con- | solid | | Con- | solid |
| | | tent | content | | tent | content | | tent | content |
| | | (% by | (% by | | (% by | (% by | | (% by | (% by |
| | Kind | mass) | mass) | Kind | mass) | mass) | Kind | mass) | mass) |
| Example | Xanthine | 0.2 | 2.9 | MDEA | 1.0 | 14.7 | Tris | 5.0 | 73.5 |
| 53 | | | | | | | | | |
| Example | Xanthine | 0.2 | 2.9 | MDEA | 1.0 | 14.7 | Tris | 5.0 | 73.5 |
| 54 | | | | | | | | | |
| Example | Xanthine | 0.2 | 2.9 | MDEA | 1.0 | 14.7 | Tris | 5.0 | 73.5 |
| 55 | | | | | | | | | |
| Example | Xanthine | 0.2 | 2.9 | MDEA | 1.0 | 14.7 | Tris | 5.0 | 73.5 |
| 56 | | | | | | | | | |
| Example | Xanthine | 0.2 | 2.9 | MDEA | 1.0 | 14.7 | Tris | 5.0 | 73.5 |
| 57 | | | | | | | | | |
| Example | Xanthine | 0.2 | 2.9 | MDEA | 1.0 | 14.7 | Tris | 5.0 | 73.5 |
| 58 | | | | | | | | | |
| Example | Xanthine | 0.2 | 2.9 | MDEA | 1.0 | 14.7 | Tris | 5.0 | 73.5 |
| 59 | | | | | | | | | |
| Example | Xanthine | 0.2 | 2.7 | MDEA/Ph-DEA | 1.0/1.0 | 27.4 | Tris | 5.0 | 68.5 |
| 60 | | | | | | | | | |
| Example | Xanthine | 0.2 | 3.1 | MDEA | 1.0 | 15.6 | Tris | 5.0 | 78.1 |
| 61 | | | | | | | | | |
| Example | Xanthine | 0.2 | 2.7 | MDEA | 1.0 | 13.5 | Tris | 6.0 | 81.1 |
| 62 | | | | | | | | | |
| Example | Xanthine/ | 0.2/0.2 | 6.2 | MDEA | 1.0 | 15.4 | Tris | 5.0 | 76.9 |
| 63 | adenine | | | | | | | | |
| Example | Xanthine | 0.2 | 3.2 | MDEA | 1.0 | 15.9 | Tris/choline | 2.5/2.5 | 79.4 |
| 64 | | | | | | | | | |
| Example | Xanthine | 0.2 | 3.1 | MDEA | 1.0 | 15.6 | Tris | 5.0 | 78.1 |
| 65 | | | | | | | | | |
| Example | Xanthine | 0.2 | 3.1 | MDEA | 1.0 | 15.6 | Tris | 5.0 | 78.1 |
| 66 | | | | | | | | | |
| Example | Xanthine | 0.2 | 3.1 | MDEA | 1.0 | 15.6 | Tris | 5.0 | 78.1 |
| 67 | | | | | | | | | |
| Example | Xanthine | 0.2 | 3.1 | MDEA | 1.0 | 15.6 | Tris | 5.0 | 78.1 |
| 68 | | | | | | | | | |
| Example | Xanthine | 0.2 | 3.1 | MDEA | 1.0 | 15.6 | Tris | 5.0 | 78.1 |
| 69 | | | | | | | | | |
| Example | Xanthine | 0.2 | 3.1 | MDEA | 1.0 | 15.6 | Tris | 5.0 | 78.1 |
| 70 | | | | | | | | | |
| Example | Xanthine | 0.2 | 2.7 | MDEA | 1.0 | 13.7 | Tris | 5.0 | 68.5 |
| 71 | | | | | | | | | |
| Example | Xanthine | 0.2 | 2.7 | MDEA | 1.0 | 13.7 | Tris | 5.0 | 68.5 |
| 72 | | | | | | | | | |

| | Cleaning liquid for semiconductor substrate | | | | | | | | | |
|---|---|---|---|---|---|---|---|---|---|---|
| | Organic acid | | | Other additives | | | | | | |
| | | | Concen- | | | Concen- | | | Clean- | Ruthe- |
| | | | tration of | | | tration of | | | ing | nium |
| | | Con- | solid | | Con- | solid | | pH | perfor- | oxide |
| | | tent | content | | tent | content | | before | mance | dis- |
| | | (% by | (% by | | (% by | (% by | (B)/ | dilu- | (organic | solving |
| | Kind | mass) | mass) | Kind | mass) | mass) | (A) | tion | residue) | ability |
| Example | Tartaric | 0.1 | 1.5 | Polyacrilyic acid | 0.5 | 7.4 | 0.2 | 12.5 | A | A |
| 53 | acid | | | (Mw = 700,000) | | | | | | |
| Example | Tartaric | 0.1 | 1.5 | Polyacrilyic acid | 0.5 | 7.4 | 0.2 | 12.5 | A | A |
| 54 | acid | | | (Mw = 55,000) | | | | | | |
| Example | Tartaric | 0.1 | 1.5 | Polyacrilyic acid | 0.5 | 7.4 | 0.2 | 12.5 | A | A |
| 55 | acid | | | (Mw = 6,000) | | | | | | |
| Example | Tartaric | 0.1 | 1.5 | Polymaleic acid | 0.5 | 7.4 | 0.2 | 12.5 | A | A |
| 56 | acid | | | (Mw = 2,000) | | | | | | |
| Example | Tartaric | 0.1 | 1.5 | Styrene-maleic | 0.5 | 7.4 | 0.2 | 12.5 | A | A |
| 57 | acid | | | acid copolymer | | | | | | |
| Example | Tartaric | 0.1 | 1.5 | Styrene-maleic | 0.5 | 7.4 | 0.2 | 12.5 | A | A |
| 58 | acid | | | acid half ester | | | | | | |
| | | | | copolymer | | | | | | |
| Example | Tartaric | 0.1 | 1.5 | Naphthalene | 0.5 | 7.4 | 0.2 | 12.5 | A | A |
| 59 | acid | | | sulfonate | | | | | | |
| | | | | formalin | | | | | | |
| | | | | condensate | | | | | | |
| | | | | Na salt | | | | | | |
| Example | Tartaric | 0.1 | 1.4 | — | — | — | 0.1 | 12.5 | A | A |
| 60 | acid | | | | | | | | | |
| Example | Tartaric | 0.1 | 1.6 | 1,2,4-triazole | 0.1 | 1.6 | 0.2 | 12.5 | A | A |
| 61 | acid | | | | | | | | | |
| Example | Tartaric | 0.1 | 1.4 | 1,2,3-triazole | 0.1 | 1.4 | 0.2 | 12.5 | A | A |
| 62 | acid | | | | | | | | | |
| Example | Tartaric | 0.1 | 1.5 | — | — | — | 0.4 | 12.5 | A | A |
| 63 | acid | | | | | | | | | |
| Example | Tartaric | 0.1 | 1.6 | — | — | — | 0.2 | 12.5 | A | A |
| 64 | acid | | | | | | | | | |
| Example | Tartaric | 0.1/0.1 | 3.1 | — | — | — | 0.2 | 12.5 | A | A |
| 65 | acid/ | | | | | | | | | |
| | citric | | | | | | | | | |
| | acid | | | | | | | | | |
| Example | Tartaric | 0.1 | 1.6 | Nonionic X | 0.1 | 1.6 | 0.2 | 12.5 | A | A |
| 66 | acid | | | | | | | | | |
| Example | Tartaric | 0.1 | 1.6 | Cysteine | 0.1 | 1.6 | 0.2 | 12.5 | A | A |
| 67 | acid | | | | | | | | | |
| Example | Tartaric | 0.1 | 1.6 | Thioglycerol | 0.1 | 1.6 | 0.2 | 12.5 | A | A |
| 68 | acid | | | | | | | | | |
| Example | Tartaric | 0.1 | 1.6 | 3-mercapto- | 0.1 | 1.6 | 0.2 | 12.5 | A | A |
| 69 | acid | | | 1,2,4-triazole | | | | | | |
| Example | Tartaric | 0.1 | 1.6 | Polyethylene | 0.1 | 1.6 | 0.2 | 12.5 | A | A |
| 70 | acid | | | glycol | | | | | | |
| Example | Tartaric | 0.1 | 1.4 | Iodic acid | 1.0 | 13.7 | 0.2 | 12.5 | A | A |
| 71 | acid | | | | | | | | | |
| Example | Tartaric | 0.1 | 1.4 | Periodic acid | 1.0 | 13.7 | 0.2 | 12.5 | A | A |
| 72 | acid | | | | | | | | | |

TABLE 4

| | Cleaning liquid for semiconductor substrate | | | | | | | | |
|---|---|---|---|---|---|---|---|---|---|
| | Purine compound (B) | | | Compound (A) | | | Tertiary ammonium compound | | |
| | | | Concentration | | | Concentration | | | Concentration |
| | | Content | of solid | | Content | of solid | | Content | of solid |
| | | (% by | content | | (% by | content | | (% by | content |
| | Kind | mass) | (% by mass) | Kind | mass) | (% by mass) | Kind | mass) | (% by mass) |
| Example | Xanthine | 0.2 | 2.8 | MDEA | 1.0 | 13.9 | Tris | 5.0 | 69.4 |
| 73 | | | | | | | | | |
| Example | Xanthine | 0.2 | 2.8 | MDEA | 1.0 | 13.9 | Tris | 5.0 | 69.4 |
| 74 | | | | | | | | | |
| Example | Xanthine | 0.2 | 2.8 | MDEA | 1.0 | 13.9 | Tris | 5.0 | 69.4 |
| 75 | | | | | | | | | |
| Example | Xanthine | 0.2 | 2.8 | MDEA | 1.0 | 13.9 | Tris | 5.0 | 69.4 |
| 76 | | | | | | | | | |
| Example | Xanthine | 0.2 | 2.8 | MDEA | 1.0 | 13.9 | Tris | 5.0 | 69.4 |
| 77 | | | | | | | | | |
| Example | Xanthine | 0.2 | 3.2 | MDEA | 1.0 | 16.1 | ETMAH | 5.0 | 80.6 |
| 78 | | | | | | | | | |
| Example | Xanthine | 0.2 | 3.2 | MDEA | 1.0 | 16.1 | Tris/ETMAH | 2.5/2.5 | 80.6 |
| 79 | | | | | | | | | |
| Example | Xanthine | 0.2 | 3.2 | MDEA | 1.0 | 16.1 | Tris | 5.0 | 80.6 |
| 80 | | | | | | | | | |
| Example | Xanthine | 0.2 | 3.2 | MDEA | 1.0 | 15.9 | Tris | 5.0 | 79.4 |
| 81 | | | | | | | | | |
| Example | Xanthine | 0.2 | 3.2 | MDEA | 1.0 | 15.9 | ETMAH | 6.0 | 79.4 |
| 82 | | | | | | | | | |
| Example | Adenine | 0.2 | 3.2 | MDEA | 1.0 | 15.9 | Tris | 5.0 | 79.4 |
| 83 | | | | | | | | | |
| Example | Adenine | 0.2 | 3.2 | MDEA | 1.0 | 15.9 | ETMAH | 5.0 | 79.4 |
| 84 | | | | | | | | | |
| Example | Adenine | 0.2 | 3.2 | MDEA | 1.0 | 15.9 | Tris | 5.0 | 79.4 |
| 85 | | | | | | | | | |
| Example | Adenine | 0.2 | 3.2 | MDEA | 1.0 | 15.9 | ETMAH | 5.0 | 79.4 |
| 86 | | | | | | | | | |
| Example | Adenine | 0.2 | 3.2 | MDEA | 1.0 | 15.9 | Tris | 5.0 | 79.4 |
| 87 | | | | | | | | | |
| Example | Adenine | 0.2 | 3.2 | MDEA | 1.0 | 15.9 | ETMAH | 5.0 | 79.4 |
| 88 | | | | | | | | | |
| Example | Adenine | 0.2 | 2.7 | MDEA | 1.0 | 13.7 | Tris | 5.0 | 68.5 |
| 89 | | | | | | | | | |
| Example | Adenine | 0.2 | 2.7 | MDEA | 1.0 | 13.7 | ETMAH | 5.0 | 68.5 |
| 90 | | | | | | | | | |
| Example | Adenine | 0.2 | 2.7 | MDEA | 1.0 | 13.7 | ETMAH | 5.0 | 68.5 |
| 91 | | | | | | | | | |
| Example | Adenine | 0.2 | 2.7 | MDEA | 1.0 | 13.7 | ETMAH | 5.0 | 68.5 |
| 92 | | | | | | | | | |
| Example | Adenine | 0.2 | 4.7 | MDEA | 1.0 | 23.3 | — | — | — |
| 93 | | | | | | | | | |
| Example | Adenine | 0.2 | 4.7 | MDEA | 1.0 | 23.3 | — | — | — |
| 94 | | | | | | | | | |

| | Cleaning liquid for semiconductor substrate | | | | | | | | | Ruthe- |
|---|---|---|---|---|---|---|---|---|---|---|
| | Organic acid | | | Other additives | | | | | Cleaning | nium |
| | | | Concentration | | | Concentration | | pH | perfor- | oxide |
| | | Content | of solid | | Content | of solid | | before | mance | dis- |
| | | (% by | content | | (% by | content | (B)/ | dilu- | (organic | solving |
| | Kind | mass) | (% by mass) | Kind | mass) | (% by mass) | (A) | tion | residue) | ability |
| Example | — | — | — | Morpholine | 1.0 | 13.9 | 0.2 | 12.5 | B | B |
| 73 | | | | | | | | | | |
| Example | — | — | — | Tetramethyl- | 1.0 | 13.9 | 0.2 | 12.5 | A | A |
| 74 | | | | guanidine | | | | | | |
| Example | — | — | — | DABCO | 1.0 | 13.9 | 0.2 | 12.5 | A | B |
| 75 | | | | | | | | | | |
| Example | — | — | — | DBU | 1.0 | 13.9 | 0.2 | 12.5 | A | A |
| 76 | | | | | | | | | | |
| Example | — | — | — | DBN | 1.0 | 13.9 | 0.2 | 12.5 | A | B |
| 77 | | | | | | | | | | |
| Example | — | — | — | — | — | — | 0.2 | 12.5 | B | B |
| 78 | | | | | | | | | | |
| Example | — | — | — | — | — | — | 0.2 | 12.5 | B | B |
| 79 | | | | | | | | | | |
| Example | — | — | — | — | — | — | 0.2 | 12.5 | B | B |
| 80 | | | | | | | | | | |
| Example | Succinic | 0.1 | 1.6 | — | — | — | 0.2 | 12.5 | A | A |
| 81 | acid | | | | | | | | | |
| Example | Succinic | 0.1 | 1.6 | — | — | — | 0.2 | 12.5 | A | A |
| 82 | acid | | | | | | | | | |
| Example | Succinic | 0.1 | 1.6 | — | — | — | 0.2 | 12.5 | C | A |
| 83 | acid | | | | | | | | | |
| Example | Succinic | 0.1 | 1.6 | — | — | — | 0.2 | 12.5 | C | A |
| 84 | acid | | | | | | | | | |
| Example | EDTPO | 0.1 | 1.6 | — | — | — | 0.2 | 12.5 | C | A |
| 85 | | | | | | | | | | |
| Example | EDTPO | 0.1 | 1.6 | — | — | — | 0.2 | 12.5 | C | A |
| 86 | | | | | | | | | | |
| Example | HEDPO | 0.1 | 1.6 | — | — | — | 0.2 | 12.5 | C | A |
| 87 | | | | | | | | | | |
| Example | HEDPO | 0.1 | 1.6 | — | — | — | 0.2 | 12.5 | C | A |
| 88 | | | | | | | | | | |
| Example | EDTPO | 0.1 | 1.4 | PMDTA | 1.0 | 13.7 | 0.2 | 12.5 | B | A |
| 89 | | | | | | | | | | |
| Example | EDTPO | 0.1 | 1.4 | PMDTA | 1.0 | 13.7 | 0.2 | 12.5 | B | A |
| 90 | | | | | | | | | | |
| Example | EDTPO | 0.1 | 1.4 | PMDTA/ | 0.5/0.5 | 13.7 | 0.2 | 12.5 | A | A |
| 91 | | | | tetramethyl- | | | | | | |
| | | | | guanidine | | | | | | |
| Example | EDTPO | 0.1 | 1.4 | PMDTA/ | 0.5/0.5 | 13.7 | 0.2 | 12.5 | A | A |
| 92 | | | | DBU | | | | | | |
| Example | EDTPO | 0.1 | 2.3 | PMDTA/ | 1.0/2.0 | 69.8 | 0.2 | 12.5 | B | A |
| 93 | | | | tetramethyl- | | | | | | |
| | | | | guanidine | | | | | | |
| Example | EDTPO | 0.1 | 2.3 | PMDTA/ | 1.0/2.0 | 69.8 | 0.2 | 12.5 | B | A |
| 94 | | | | DBU | | | | | | |

TABLE 5

| | Cleaning liquid for semiconductor substrate | | | | | | | | |
|---|---|---|---|---|---|---|---|---|---|
| | Purine compound (B) | | | Compound (A) | | | Tertiary ammonium compound | | |
| | | | Concen- | | | Concen- | | | Concen- |
| | | | tration of | | | tration of | | | tration of |
| | | | solid | | | solid | | | solid |
| | | Content | content | | Content | content | | Content | content |
| | Kind | (% by mass) | (% by mass) | Kind | (% by mass) | (% by mass) | Kind | (% by mass) | (% by mass) |
| Example | Adenine | 0.2 | 2.2 | MDEA | 2.0 | 21.5 | Tris | 5.0 | 53.8 |
| 95 | | | | | | | | | |
| Example | Adenine | 0.05 | 1.1 | MDEA | 1.0 | 21.7 | Tris | 2.5 | 54.3 |
| 96 | | | | | | | | | |
| Example | Adenine | 0.2 | 2.4 | MDEA | 1.0 | 12.0 | Tris | 5.0 | 60.2 |
| 97 | | | | | | | | | |
| Example | Adenine | 0.05 | 1.3 | MDEA | 0.2 | 5.3 | Tris | 2.5 | 65.8 |
| 98 | | | | | | | | | |
| Example | Adenine | 0.2 | 2.8 | MDEA | 1.0 | 13.9 | Tris | 5.0 | 69.4 |
| 99 | | | | | | | | | |
| Example | Adenine | 0.2 | 4.8 | MDEA | 0.5 | 11.9 | Tris | 2.5 | 59.5 |
| 100 | | | | | | | | | |
| Example | Xanthine | 0.2 | 2.8 | MDEA | 1.0 | 13.9 | Tris | 5.0 | 69.4 |
| 101 | | | | | | | | | |
| Example | Xanthine | 0.2 | 4.8 | MDEA | 0.5 | 11.9 | Tris | 2.5 | 59.5 |
| 102 | | | | | | | | | |
| Example | Adenine | 0.2 | 2.8 | MDEA | 1.0 | 13.9 | Tris | 5.0 | 69.4 |
| 103 | | | | | | | | | |
| Example | Adenine | 0.2 | 4.8 | MDEA | 0.5 | 11.9 | Tris | 2.5 | 59.5 |
| 104 | | | | | | | | | |
| Example | Adenine | 0.2 | 2.7 | DMAMP/MAMP | 4.5/0.5 | 68.5 | — | — | — |
| 105 | | | | | | | | | |
| Example | Adenine | 0.05 | 1.2 | DMAMP/MAMP | 2.99/0.01 | 73.9 | — | — | — |
| 106 | | | | | | | | | |
| Example | Adenine | 0.2 | 3.8 | DMAMP | 4.0 | 76.9 | — | — | — |
| 107 | | | | | | | | | |
| Example | Xanthine | 0.2 | 3.8 | DMAMP | 4.0 | 76.9 | — | — | — |
| 108 | | | | | | | | | |
| Example | Adenine | 0.2 | 3.8 | MDEA | 4.0 | 76.9 | — | — | — |
| 109 | | | | | | | | | |
| Example | Adenine | 0.2 | 3.8 | DMAE | 4.0 | 76.9 | — | — | — |
| 110 | | | | | | | | | |
| Example | Adenine | 0.2 | 3.8 | BDEA | 4.0 | 76.9 | — | — | — |
| 111 | | | | | | | | | |
| Example | Adenine | 0.2 | 3.8 | DMAMP | 4.0 | 76.9 | — | — | — |
| 112 | | | | | | | | | |
| Example | Adenine | 0.2 | 2.7 | MDEA | 1.0 | 13.7 | Tris | 5.0 | 68.5 |
| 113 | | | | | | | | | |
| Example | Adenine | 0.2 | 4.7 | MDEA | 0.5 | 11.6 | Tris | 2.5 | 58.1 |
| 114 | | | | | | | | | |
| Example | Adenine | 0.2 | 3.8 | DMAMP | 4.0 | 75.5 | — | — | — |
| 115 | | | | | | | | | |
| Example | Adenine | 0.2 | 2.7 | MDEA | 1.0 | 13.7 | Tris | 5.0 | 68.5 |
| 116 | | | | | | | | | |
| Example | Adenine | 0.2 | 4.7 | MDEA | 0.5 | 11.6 | Tris | 2.5 | 58.1 |
| 117 | | | | | | | | | |
| Example | Adenine | 0.2 | 3.8 | DMAMP | 4.0 | 75.5 | — | — | — |
| 118 | | | | | | | | | |

| | Cleaning liquid for semiconductor substrate | | | | | | | | | |
|---|---|---|---|---|---|---|---|---|---|---|
| | Organic acid | | | Other additives | | | | | | Ruthe- |
| | | | Concen- | | | Concen- | | | Cleaning | nium |
| | | | tration of | | | tration of | | pH | perfor- | oxide |
| | | | solid | | | solid | | before | mance | dis- |
| | | Content | content | | Content | content | (B)/ | dilu- | (organic | solving |
| | Kind | (% by mass) | (% by mass) | Kind | (% by mass) | (% by mass) | (A) | tion | residue) | ability |
| Example | — | — | — | PMDTA/2-(2- | 2.0/0.1 | 22.6 | 0.1 | 12.5 | B | B |
| 95 | | | | aminoethyl- | | | | | | |
| | | | | amino)ethanol | | | | | | |
| Example | — | — | — | PMDTA/2-(2- | 1.0/0.05 | 22.8 | 0.1 | 12.3 | B | B |
| 96 | | | | aminoethyl- | | | | | | |
| | | | | amino)ethanol | | | | | | |
| Example | — | — | — | PMDTA/ | 2.0/0.1 | 25.3 | 0.2 | 12.5 | B | B |
| 97 | | | | hydrazine | | | | | | |
| Example | — | — | — | PMDTA/ | 1.0/0.05 | 27.6 | 0.3 | 12.3 | B | B |
| 98 | | | | hydrazine | | | | | | |
| Example | — | — | — | PMDTA | 1.0 | 13.9 | 0.2 | 12.5 | B | B |
| 99 | | | | | | | | | | |
| Example | — | — | — | PMDTA | 1.0 | 23.8 | 0.4 | 12.5 | B | B |
| 100 | | | | | | | | | | |
| Example | — | — | — | PMDTA | 1.0 | 13.9 | 0.2 | 12.5 | A | B |
| 101 | | | | | | | | | | |
| Example | — | — | — | PMDTA | 1.0 | 23.8 | 0.4 | 12.5 | A | B |
| 102 | | | | | | | | | | |
| Example | — | — | — | TMED | 1.0 | 13.9 | 0.2 | 12.5 | C | B |
| 103 | | | | | | | | | | |
| Example | — | — | — | TMED | 1.0 | 23.8 | 0.4 | 12.5 | C | B |
| 104 | | | | | | | | | | |
| Example | — | — | — | PMDTA/AMP | 2.0/0.1 | 28.8 | 0.04 | 11.5 | B | B |
| 105 | | | | | | | | | | |
| Example | — | — | — | PMDTA/AMP | 1.0/0.01 | 24.9 | 0.02 | 11.5 | B | B |
| 106 | | | | | | | | | | |
| Example | — | — | — | PMDTA | 1.0 | 19.2 | 0.1 | 11.5 | B | B |
| 107 | | | | | | | | | | |
| Example | — | — | — | PMDTA | 1.0 | 19.2 | 0.1 | 11.5 | A | B |
| 108 | | | | | | | | | | |
| Example | — | — | — | PMDTA | 1.0 | 19.2 | 0.1 | 11.5 | C | C |
| 109 | | | | | | | | | | |
| Example | — | — | — | PMDTA | 1.0 | 19.2 | 0.1 | 11.5 | C | C |
| 110 | | | | | | | | | | |
| Example | — | — | — | PMDTA | 1.0 | 19.2 | 0.1 | 11.5 | C | C |
| 111 | | | | | | | | | | |
| Example | — | — | — | TMED | 1.0 | 19.2 | 0.1 | 11.5 | C | B |
| 112 | | | | | | | | | | |
| Example | Succinic | 0.1 | 1.4 | PMDTA | 1.0 | 13.7 | 0.2 | 12.3 | B | A |
| 113 | acid | | | | | | | | | |
| Example | Succinic | 0.1 | 2.3 | PMDTA | 1.0 | 23.3 | 0.4 | 12.3 | B | A |
| 114 | acid | | | | | | | | | |
| Example | Succinic | 0.1 | 1.9 | PMDTA | 1.0 | 18.9 | 0.1 | 11.3 | B | A |
| 115 | acid | | | | | | | | | |
| Example | HEDPO | 0.1 | 1.4 | PMDTA | 1.0 | 13.7 | 0.2 | 12.3 | B | A |
| 116 | | | | | | | | | | |
| Example | HEDPO | 0.1 | 2.3 | PMDTA | 1.0 | 23.3 | 0.4 | 12.3 | B | A |
| 117 | | | | | | | | | | |
| Example | HEDPO | 0.1 | 1.9 | PMDTA | 1.0 | 18.9 | 0.1 | 11.3 | B | A |
| 118 | | | | | | | | | | |

From the above table, it has been confirmed that the cleaning liquid according to the embodiment of the present invention is excellent in cleaning performance and also excellent in ruthenium oxide dissolving ability.

It has been confirmed that in a case where the purine compound includes at least one selected from the group consisting of xanthine, hypoxanthine, uric acid, purine, caffeine, and theophylline, cleaning performance is more excellent, and it has been confirmed that in a case where it includes at least one selected from the group consisting of xanthine and hypoxanthine, cleaning performance is still more excellent (the comparison among Examples 1 to 10 and 99 to 102). In addition, from the same comparison, it has been confirmed that in a case where the purine compound includes at least one selected from the group consisting of compounds represented by Formulae (B5) and (B6), cleaning performance is still more excellent.

It has been confirmed that in a case where the content of the purine compound is 0.5% to 30.0% by mass with respect to the total mass of the components of the cleaning liquid excluding the solvent, cleaning performance is more excellent (the comparison between Examples 1 and 11 to 14 and Example 15, the comparison between Examples 5 and 16 and Example 17, the comparison between Examples 10 and 18 and Example 19, and the comparison between Examples 7 and 20 and Example 21).

It has been confirmed that in a case where the compound A includes at least one selected from the group consisting of MDEA, t-BDEA, Ph-DEA, EDEA, and N-MEA, ruthenium oxide dissolving ability is more excellent, and it has been confirmed that in a case where the purine compound contains MDEA, the ruthenium oxide dissolving ability is further excellent (the comparison among Examples 1 and 22 to 28).

It has been confirmed that in a case where the content of the compound represented by Formula (A) is 3.0% to 40.0% by mass with respect to the total mass of the components of the cleaning liquid for a semiconductor substrate excluding the solvent, the effect of the present invention is further improved (the comparison among Examples 1, 29 to 33, and 52).

It has been confirmed that in a case where the pH of the cleaning liquid (the pH before dilution) is 9.5 to 13.0, the effect of the present invention is further improved (the comparison among Examples 1 and 41 to 44).

It has been confirmed that in a case where the mass ratio of the content of the purine compound to the content of the compound A is 0.02 to 20.0, the effect of the present invention is further improved, and it has been confirmed that in a case where the mass ratio of the content of the purine compound to the content of the compound A is 0.05 to 10.0, the ruthenium oxide dissolving ability is further excellent (the comparison among Examples 1, 11 to 14, 30 to 33, 47, and 48).

It has been confirmed that in a case where the cleaning liquid contains the amine compound having a pKa of 8.5 or more, the effect of the present invention is further improved, and it has been confirmed that in a case where the cleaning liquid contains at least one compound selected from the group consisting of guanidine, a guanidine derivative, and a cyclic amidine compound, the ruthenium oxide dissolving ability is further excellent (the comparison among Examples 73 to 80).

It has been confirmed that in a case where the cleaning liquid contains an aliphatic tertiary amine compound, cleaning performance is more excellent (the comparison among Examples 83 to 88, 89, and 90). in addition, from the same comparison, it has been confirmed that in a case where the cleaning liquid contains N,N,N′,N″,N″-pentamethyldiethylenetriamine, cleaning performance is still more excellent (the comparison among Examples 99, 100, 103, and 104).

It has been confirmed that in a case where the cleaning liquid contains 2-(dimethylamino)-2-methyl-1-propanol as a main component, the effect of the present invention is further improved (the comparison among Examples 95 to 112).

What is claimed is:

1. A cleaning liquid for a semiconductor substrate, which is used for cleaning a semiconductor substrate, the cleaning liquid comprising:
at least one purine compound selected from the group consisting of purine and a purine derivative; and
a compound represented by Formula (A), 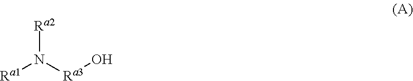
in Formula (A), R^{a1} represents an alkyl group which may have a hydroxyl group,
R^{a2} represents a hydrogen atom, an alkyl group which may have a substituent, or an aryl group which may have a substituent, and
R^{a3} represents an alkylene group which may have an oxygen atom.

2. The cleaning liquid for a semiconductor substrate according to claim 1,
wherein the purine compound includes at least one selected from the group consisting of compounds represented by Formulae (B5) and (B6), 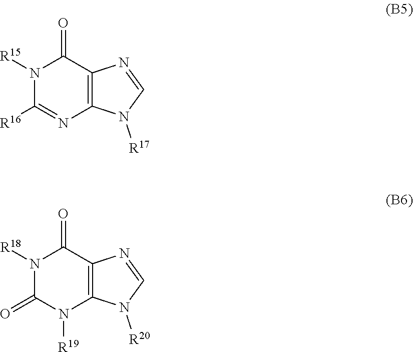
in Formula (B5), R¹⁵ and R¹⁷ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent, and
R¹⁶ represents a hydrogen atom, an alkyl group which may have a substituent, a thiol group, a hydroxyl group, a halogen atom, a sugar group which may have a substituent, or a polyoxyalkylene group-containing group which may have a substituent,
in Formula (B6), R¹⁸ to R²⁰ each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

3. The cleaning liquid for a semiconductor substrate according to claim 1,
wherein the purine compound includes at least one selected from the group consisting of xanthine, adenine, guanine, hypoxanthine, uric acid, purine, caffeine, isoguanine, theobromine, theophylline, and paraxanthine.

4. The cleaning liquid for a semiconductor substrate according to any one of claims 1 to 3,
wherein the purine compound includes at least one selected from the group consisting of xanthine and hypoxanthine.

5. The cleaning liquid for a semiconductor substrate according to any one of claims 1 to 4,
wherein the compound represented by Formula (A) includes a compound represented by Formula (A1), 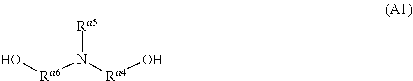
in Formula (A1), R^{a4} represents an alkylene group which may have an oxygen atom,
R^{a6} represents an alkylene group, and
R^{a5} represents an alkyl group having 1 to 5 carbon atoms, which may have a substituent, a phenyl group, or a hydrogen atom.

6. The cleaning liquid for a semiconductor substrate according to any one of claims 1 to 5,
wherein the compound represented by Formula (A) includes N-methyldiethanolamine.

7. The cleaning liquid for a semiconductor substrate according to any one of claims 1 to 6,
wherein a content of the purine compound is 0.5% to 30.0% by mass with respect to a total mass of components of the cleaning liquid for a semiconductor substrate excluding a solvent.

8. The cleaning liquid for a semiconductor substrate according to any one of claims 1 to 7,
wherein a content of the compound represented by Formula (A) is 3.0% to 40.0% by mass with respect to a total mass of components of the cleaning liquid for a semiconductor substrate excluding a solvent.

9. The cleaning liquid for a semiconductor substrate according to any one of claims 1 to 8,
wherein a mass ratio of a content of the purine compound to a content of the compound represented by Formula (A) is 0.02 to 20.0.

10. The cleaning liquid for a semiconductor substrate according to any one of claims 1 to 9,
wherein a pH is 9.5 to 13.0.

11. The cleaning liquid for a semiconductor substrate according to any one of claims 1 to 10, further comprising:
an organic acid.

12. The cleaning liquid for a semiconductor substrate according to claim 11,
wherein the organic acid includes a compound represented by Formula (D), 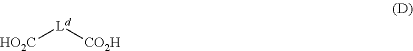
in Formula (D), La represents a single bond or a divalent linking group.

13. The cleaning liquid for a semiconductor substrate according to any one of claims 1 to 12, further comprising:
a quatemary ammonium compound.

14. The cleaning liquid for a semiconductor substrate according to claim 13,
wherein the quaternary ammonium compound includes a compound represented by Formula (C), 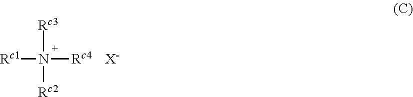
in Formula (C), R^{c1} to R^{c4} each independently represent a hydrocarbon group which may have a substituent, provided that a case where all of R^{c1} to R^{c4} represent the same group is excluded, and X⁻ represents an anion.

15. The cleaning liquid for a semiconductor substrate according to claim 13 or 14,
wherein the quaternary ammonium compound includes tris(2-hydroxyethyl)methylammonium hydroxide.

16. The cleaning liquid for a semiconductor substrate according to any one of claims 1 to 15, further comprising:
an aliphatic tertiary amine compound which is a compound different from the compound represented by Formula (A).

17. The cleaning liquid for a semiconductor substrate according to claim 16,
wherein the aliphatic tertiary amine compound has two or more nitrogen atoms.
